(19) United States
(12) Patent Application Publication
(10) Pub. No.: US 2011/0089575 A1
(43) Pub. Date: Apr. 21, 2011

(54) MULTICHIP PACKAGE AND METHOD OF MANUFACTURING THE SAME

(75) Inventor: In LEE, Hwaseong-si (KR)

(73) Assignee: Samsung Electronics Co., Ltd., Suwon-si (KR)

(21) Appl. No.: 12/835,059

(22) Filed: Jul. 13, 2010

(30) Foreign Application Priority Data
Oct. 15, 2009 (KR) P2009-98396

(51) Int. Cl. H01L 23/538

(52) U.S. Cl. 257/777; 257/786; 257/E23.169; 257/E23.175

(57) ABSTRACT

A semiconductor package includes at least one semiconductor chip mounted to a circuit board and separated from the circuit board by a predetermined distance. A support located between the circuit board and the first semiconductor chip supports the first semiconductor chip. The support has first and second ends fixed with respect to the circuit board and a center portion between the first and second ends to contact the first semiconductor chip.

### CROSS-REFERENCE TO RELATED APPLICATIONS

This U.S. non-provisional patent application claims priority under 35 U.S.C §119 of Korean Patent Application No. 2009-98396 filed on Oct. 15, 2009, the entirety of which is hereby incorporated by reference.

### BACKGROUND

1. Field of the Invention

The present general inventive concept relates to a stacked semiconductor chip package and a method of manufacturing the same.

2. Description of the Related Art

Semiconductor manufacturing technologies have improved in strength, durability, and performance and have decreased the size of semiconductor devices. However, manufacturing semiconductor packages may be expensive, time-consuming, and labor or machine-intensive.

In particular, large financial investments must be made to upgrade facilities, purchase new equipment, and conduct research to produce a new or improved stacked semiconductor package. In the case of semiconductor memory devices, for example, the process of upgrading from 64 MB DRAM to 256 MB DRAM may be costly when it requires a new wafer-fabrication process.

Semiconductor packages may be manufactured by including a plurality of semiconductor chips into one package. For example, semiconductor chips may be stacked on-atop-the-other. This semiconductor-chip stacking process results in a semiconductor package having high reliability, structural integrity, and performance without the need to design or fabricate a new wafer. For example, four 64 MB DRAM chips may be stacked on-atop-another to form a single 256 MB DRAM semiconductor package.

FIG. 1 illustrates an example of a stacked semiconductor package. As shown in FIG. 1, an upper semiconductor chip 108 may be offset from a lower semiconductor chip 104 to allow an electrode pad P2 on an upper surface of the lower semiconductor chip 104 to be electrically connected to another electrode pad P4. With such a configuration, a portion A of the upper semiconductor chip 108 may be offset from the lower semiconductor chip 104 such that it is not supported on a lower surface. In other words, a portion A of the upper semiconductor chip 108 may overhang an end of the lower semiconductor chip 104.

A wiring process may connect a wire 112 between the electrode pad P3 and pad P1 and a wire 110 between electrode pad P2 on the lower semiconductor chip and pad P4 on the substrate. In addition, pads P5 on a lower surface of the substrate P100 may be electrically connected to the pads P1 and P4 on the upper surface of the substrate, so that when the pads P2, P3 on the semiconductor chips 104, 108 are connected to the pads P1, P4 on the substrate, the semiconductor chips 104, 108 may be electrically connected to the pads P5. The pads P5 may be connected to an external electrical device (not shown).

However, when the wiring process is performed to attach a wire 112 to a pad P3 of the upper semiconductor chip 108 and a pad P1 of the substrate 100, the wiring process may generate pressure on the overhang portion A. In addition, when the stacked semiconductor chips 104, 108 are enclosed in a molding 114, the molding process may generate pressure on the overhang portion A. As a result of this pressure, the upper semiconductor chip 108 may crack, the connection between the upper semiconductor chip and the wire 112 may weaken or fail, or the bond between the upper and lower semiconductor chips 104, 108 may weaken or fail.

Consequently, a feature is needed to increase a bonding and/or wiring strength of a stacked semiconductor package at a low cost and high efficiency.

### SUMMARY

Exemplary embodiments of the present general inventive concept provide a device and method to support an overhang of a semiconductor chip in a stacked semiconductor package.

Additional aspects and utilities of the present general inventive concept will be set forth in part in the description which follows and, in part, will be obvious from the description, or may be learned by practice of the general inventive concept.

Features and/or utilities of the present general inventive concept may be realized by a semiconductor package including a circuit board, a first semiconductor chip mounted to the circuit board to be separated from the circuit board by a predetermined distance, and a support located between the circuit board and the first semiconductor chip to support the first semiconductor chip, the support having first and second ends fixed with respect to the circuit board and a center portion between the first and second ends to contact the first semiconductor chip.

The semiconductor package may include a second semiconductor chip mounted to the circuit board. The first semiconductor chip may be mounted to an upper surface of the second semiconductor chip, an overhang portion of the first semiconductor chip may extend past an end of the second semiconductor chip in a first direction, and the center portion of the support may contact the first semiconductor chip on a bottom surface of the overhang portion.

The support may have a length that runs parallel to the first direction. Alternatively, the support may have a length that runs perpendicular to the first direction.

The support may include a first wire having a length running perpendicular to the first direction and a second wire having a length running parallel to the first direction.

One of the first and second wire may be mounted to have a center portion beneath a center portion of the other of the first and second wire to support the other of the first and second wire.

The semiconductor package may further include a third semiconductor chip mounted to an upper surface of the first semiconductor chip. An overhang portion of the third semiconductor chip may extend past an end of the overhang portion of the first semiconductor chip in the first direction, and the support may include a first support to support to contact a bottom surface of the first overhang portion of the first semiconductor chip and a second support to support the third semiconductor chip by contacting a bottom surface of the second overhang portion of the third semiconductor chip.

The first support may have a first height and the second support may have a second height greater than the first height.

The first and second ends of the support may be mounted to an upper surface of the circuit board.

The support may include a wire. The wire may be a dummy wire that does not transmit electrical signals from one end to the other end.

The semiconductor package may include at least one transmission wire to electrically connect a bonding pad of the first semiconductor chip to a bonding pad of the circuit board, and the dummy wire may have a thickness greater than a thickness of the transmission wire. In addition, the dummy wire may be composed of a material different than the transmission wire.

The support may further include a polymer material to support the wire, and the wire may be positioned over an upper surface of the polymer material.

The semiconductor package may further include a second semiconductor chip mounted to the circuit board and a third semiconductor chip mounted to an upper surface of the second semiconductor chip to expose a bonding pad portion of the second semiconductor chip located on an upper surface of the second semiconductor chip. The first semiconductor chip may be mounted to the third semiconductor chip, an overhang portion of the first semiconductor chip may extend past an end of the third semiconductor chip to be located over the bonding pad portion of the upper surface of the second semiconductor chip, and at least one end of the support may be mounted to the bonding pad portion of the second semiconductor chip.

Each end of the support may be mounted to the bonding pad portion of the second semiconductor chip.

A first end of the support may be mounted to the bonding pad portion of the second semiconductor chip, and a second end of the support may be mounted to the circuit board.

Features and/or utilities of the present general inventive concept may also be realized by a semiconductor package including a circuit board, a first semiconductor chip mounted to be fixed with respect to the circuit board and spaced from the circuit board by a predetermined distance, and a support mounted to the circuit board to provide support to the first semiconductor chip by providing a linear pressure to a bottom surface of the first semiconductor chip.

Features and/or utilities of the present general inventive concept may also be realized by a semiconductor package including a circuit board, a first semiconductor chip electrically connected to the circuit board and spaced from the circuit board by a predetermined distance, and a support mounted to the circuit board to provide support to the first semiconductor chip by providing a linear pressure to a bottom surface of the first semiconductor chip.

Features and/or utilities of the present general inventive concept may also be realized by a semiconductor package including a circuit board, a semiconductor chip positioned over and spaced-apart from the circuit board by a predetermined distance and electrically connected to the circuit board, and a support mounted on the circuit board to support the semiconductor chip, the support including at least two pads fixed to the circuit board and spaced apart from each other and a material connecting the at least two pads and contacting the semiconductor chip.

Features and/or utilities of the present general inventive concept may also be realized by a semiconductor package including a circuit board, a semiconductor chip electrically connected to the circuit board and spaced-apart from the circuit board by a predetermined distance, and a support mounted on the circuit board to support the semiconductor chip to maintain the predetermined distance with respect to the circuit board.

Features and/or utilities of the present general inventive concept may also be realized by a semiconductor package including a circuit board, a semiconductor chip positioned over the circuit board, and a support having a bottom formed on the circuit board in a first, lengthwise direction and a top having a height sufficient to contact the semiconductor chip. The top and at least two ends of the bottom may form a substantially triangular shape.

Features and/or utilities of the present general inventive concept may also be realized by a semiconductor package including a circuit board, a semiconductor chip positioned over the circuit board, and a support having two ends formed on the circuit in a first, lengthwise direction and a top connected to the two ends and forming an arch shape having a height sufficient to contact the semiconductor chip.

Features and/or utilities of the present general inventive concept may also be realized by a semiconductor package including a circuit board, a semiconductor chip, and a support having a bottom to contact with the circuit board in a first geometric area of the circuit board and a top to contact the semiconductor chip in a second geometric area of the semiconductor chip. The first geometric area may have a non-circular shape and the second geometric area may have a substantially rectangular shape.

Features and/or utilities of the present general inventive concept may also be realized by a semiconductor package including a circuit board, a semiconductor chip, and a support to support the semiconductor chip, to contact the circuit board in a geometric area of the circuit board, and to contact the semiconductor chip along a geometric line segment.

Features and/or utilities of the present general inventive concept may also be realized by a semiconductor package including a circuit board, a semiconductor chip in a fixed position with respect to the circuit board, and a support to support the semiconductor chip by contacting the circuit board in a first geometric area of the circuit board and to contact the semiconductor chip in a second geometric area of the semiconductor chip. The first geometric area may be different from the second geometric area.

Features and/or utilities of the present general inventive concept may also be realized by a semiconductor package including a circuit board, a first semiconductor chip positioned over a first area of the circuit board, a second semiconductor chip positioned over a second area of the circuit board, the second area having an overlapping area and a non-overlapping area with the first area, and a support located in the non-overlapping area and having a length in a first direction and a width in a second direction. The length may be longer than the width.

Features and/or utilities of the present general inventive concept may also be realized by a semiconductor package including a circuit board, a support formed on the circuit board and having a length in a first direction, and a semiconductor chip positioned a predetermined distance over the circuit board in a longitudinal direction having a predetermined angle with respect to the first direction, the semiconductor chip contacting the support and being electrically connected to the circuit board.

The support may have a length and a width, and at least one of the length and width may be greater than the other one of the length and width.

The support may include at least two ends separated from each other to contact the circuit board, and a middle portion connecting the two ends to contact the semiconductor chip.

The support may have a height substantially same as the predetermined distance between the semiconductor chip and the circuit board.

The support may be an elastic material.

The support may be made of a polymer.

The semiconductor package may include a second semiconductor chip mounted to the circuit board, and the support may be mounted on the second semiconductor chip to support the first semiconductor chip.

The semiconductor package may also include a second semiconductor chip positioned between the circuit board and the semiconductor chip and positioned in a direction different from the first semiconductor chip, and the support may be positioned in a direction parallel to one of the first semiconductor and the second semiconductor.

Features and/or utilities of the present general inventive concept may also be realized by an electronic apparatus including a circuit board, a first semiconductor chip mounted to be fixed with respect to the circuit board and spaced from the circuit board by a predetermined distance, and a support mounted to the circuit board to provide support to the first semiconductor chip by providing a linear pressure to a bottom surface of the first semiconductor chip.

Features and/or utilities of the present general inventive concept may also be realized by a memory storage device including a memory unit and a controller. The memory unit may include a stacked semiconductor package. The stacked semiconductor package may include a circuit board, a first semiconductor chip mounted to the circuit board to be separated from the circuit board by a predetermined distance, and a support located between the circuit board and the first semiconductor chip to support the first semiconductor chip, the support having first and second ends fixed with respect to the circuit board and a center portion between the first and second ends to contact the first semiconductor chip. The controller may read data from and write data to the stacked semiconductor package.

### BRIEF DESCRIPTION OF THE DRAWINGS

These and/or other aspects and utilities of the present general inventive concept will become apparent and more readily appreciated from the following description of the embodiments, taken in conjunction with the accompanying drawings which are briefly described below.

FIG. 1 illustrates a stacked semiconductor package.

FIGS. 2A-2I illustrate side and top views of a stacked semiconductor package according to embodiments of the present general inventive concept.

FIGS. 3A and 3B illustrate two perspectives of a stacked semiconductor package according to another embodiment of the present general inventive concept.

FIGS. 4A-4C illustrate embodiments of a dummy wire according to the general inventive concept.

FIGS. 5A-5D illustrate plan configurations of the dummy wire according to an the present general inventive concept.

FIGS. 6A-D illustrate a method of manufacturing a stacked semiconductor package according to an embodiment of the present general inventive concept.

FIG. 7 illustrates an end view of a stacked semiconductor package according to an embodiment of the present general inventive concept.

FIGS. 8A-8C illustrate a method of manufacturing a stacked semiconductor package according to another embodiment of the present general inventive concept.

FIGS. 9A-9D illustrate a method of manufacturing a stacked semiconductor package according to another embodiment of the present general inventive concept.

FIGS. 10A-10C illustrate a method of manufacturing a stacked semiconductor package according to another embodiment of the present general inventive concept.

FIGS. 11A-11C illustrate a method of manufacturing a stacked semiconductor package according to another embodiment of the present general inventive concept.

FIGS. 12A-12C illustrate a method of manufacturing a stacked semiconductor package according to another embodiment of the present general inventive concept.

FIGS. 13A-13C illustrate a method of manufacturing a stacked semiconductor package according to another embodiment of the present general inventive concept.

FIGS. 14A-14H illustrate a stacked semiconductor package according to an embodiment of the present general inventive concept.

FIGS. 15A and 15B illustrate a stacked semiconductor package according to an embodiment of the present general inventive concept.

FIG. 16 illustrates a stacked semiconductor package according to an embodiment of the present general inventive concept.

FIG. 17 illustrates a stacked semiconductor package according to an embodiment of the present general inventive concept.

FIGS. 18A-18C illustrate dummy wires according to embodiments of the present general inventive concept.

FIG. 19 illustrates a block diagram of a memory device according to an embodiment of the present general inventive concept.

FIG. 20 illustrates a block diagram of a computing device according to an embodiment of the present general inventive concept.

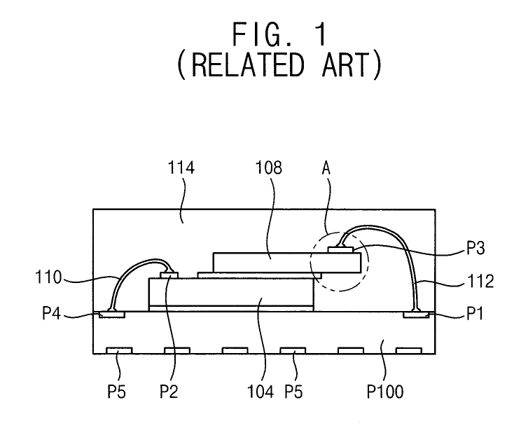

### DETAILED DESCRIPTION OF THE EMBODIMENTS

Reference will now be made in detail to the embodiments of the present general inventive concept, examples of which are illustrated in the accompanying drawings, wherein like reference numerals may be used to refer to like elements throughout. The embodiments are described below to explain the present general inventive concept by referring to the figures.

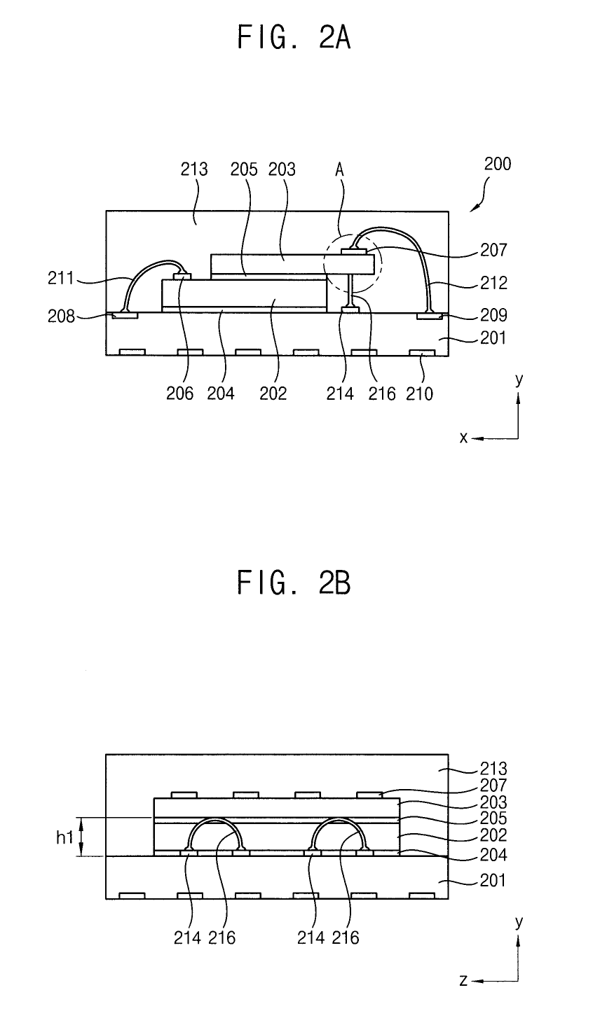

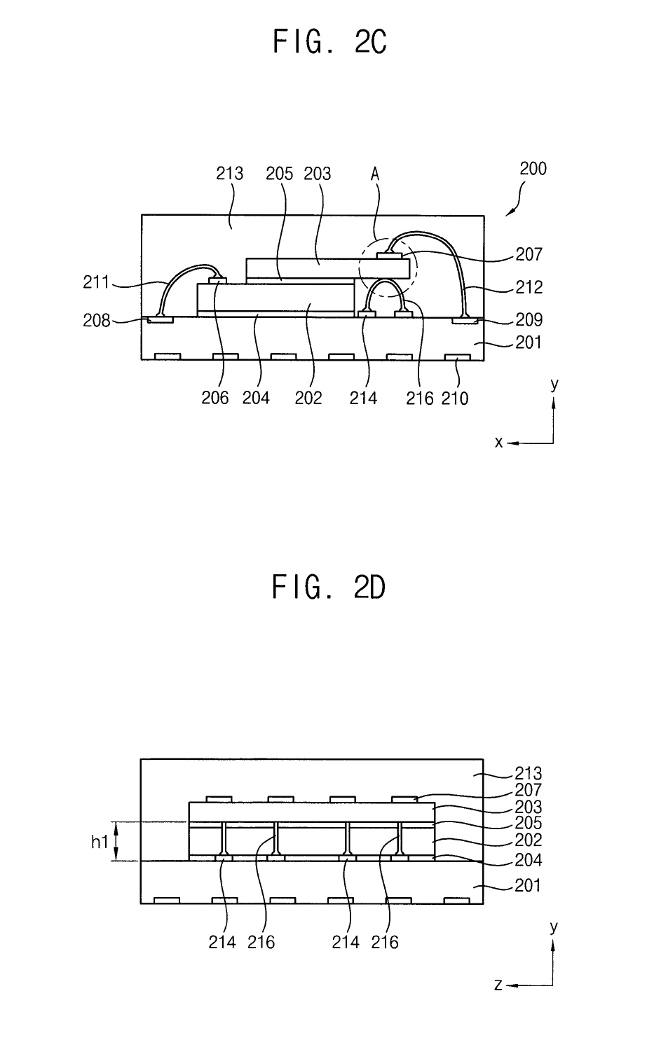

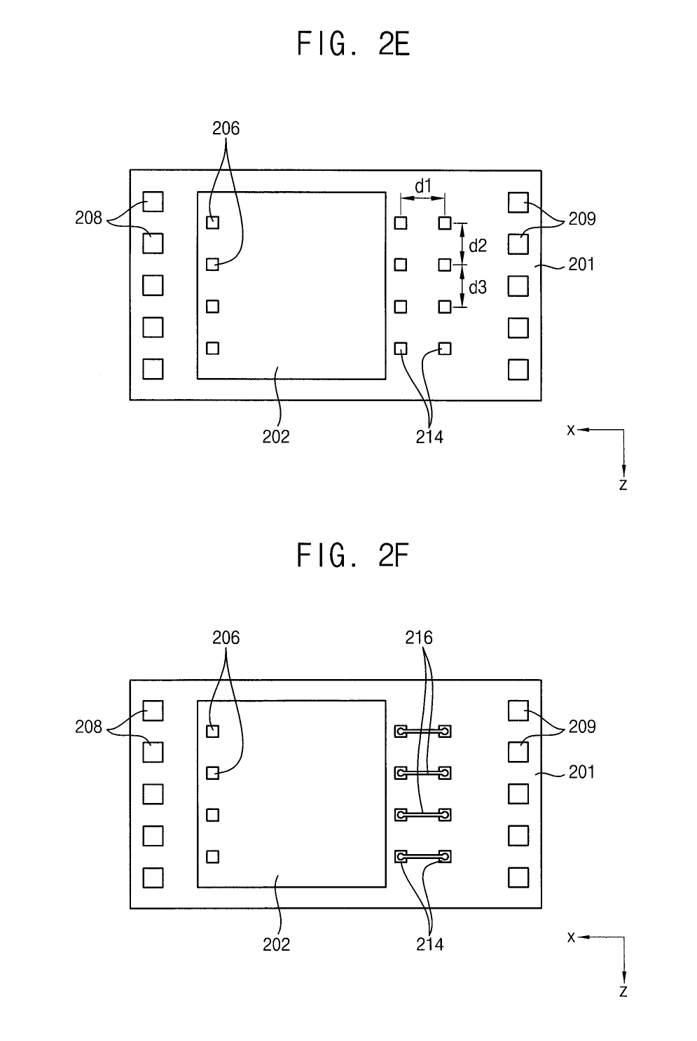

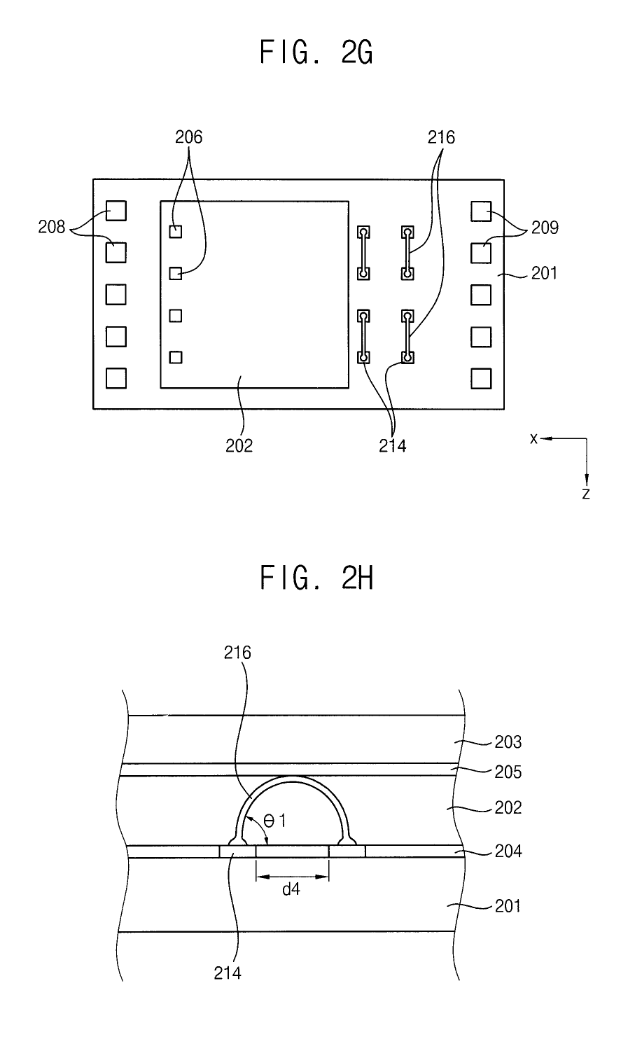

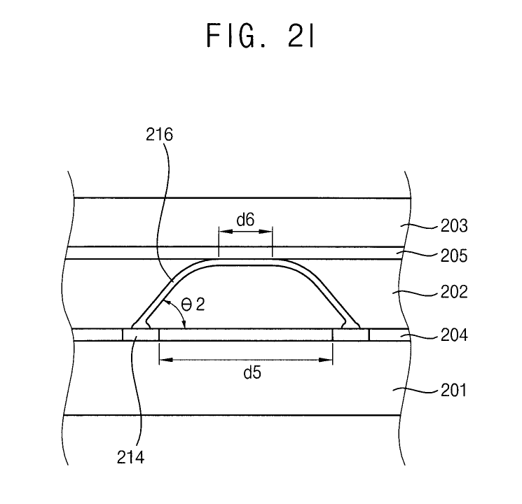

FIGS. 2A and 2B illustrate a stacked semiconductor package 200 including a dummy wire 216 to support an overhang portion A of the upper semiconductor chip 203.

The stacked semiconductor package 200 of FIGS. 2A and 2B includes a substrate 201, which may include first bonding pads 208 and second bonding pads 209 on its upper surface. The substrate 201 may also include bonding pads 210 on its bottom surface. Wiring within the substrate 201 may connect the bonding pads 208, 209 of the upper surface with the bonding pads 210 of the bottom surface.

A first semiconductor chip 202 may be mounted on the substrate 201 and fixed with adhesive 204. The first semiconductor chip 202 may include a bonding pad 206 on its upper surface, and the bonding pad 206 may be connected to the bonding pad 208 of the substrate 201 with a wire 211. A second semiconductor chip 203 may be mounted on the first semiconductor chip 202 and fixed with an adhesive 205. The second semiconductor chip 203 is mounted on the first semiconductor chip 202 so that the chips are stacked vertically, or in the direction y. When a portion of the second semiconductor chip 203 covers bonding pads of the first semiconductor chip 202, a redistribution layer (not shown) may also be positioned between the first and second semiconductor chips 202, 203.

The adhesive layer 205 may be a layer to electrically separate semiconductor chips 202 and 203 or to space semiconductor chips 202 and 203 apart from each other. The layer may have a conductive line to perform a redistributive function of electrically connecting the semiconductor chips 202 and 203.

The second semiconductor chip 203 may include at least one bonding pad 207 on its upper surface. The bonding pad 207 may be connected to the bonding pad 209 of the substrate with a wire 212. In FIG. 2B, the wire 212 is omitted for clarity. The stacked semiconductor package may be sealed by a mold 213. For example, an epoxy mold compound may be used to fill in the area surrounding the semiconductor chips 202, 203 to insulate and protect the chips.

The second semiconductor chip 203 may be mounted on the first semiconductor chip 202 so that the second semiconductor chip 203 is offset from the first semiconductor chip 202 in a horizontal direction x. A portion “A” of the second semiconductor chip 203 may overhang the first semiconductor chip 202, so that no portion of the first semiconductor chip 202 is located between the bottom of the second semiconductor chip 203 and the substrate 201.

A dummy wire 216 may be formed on bonding pads 214 of the first semiconductor chip 202 beneath the overhang A to provide support to the overhang portion A. The dummy wire 216 may have a “U” shape, with the ends connected to the bonding pads. The dummy wire 216 may have a height h1 sufficient to contact and support the bottom side of the second semiconductor chip 203. As shown in FIGS. 2A and 2B, the dummy wires 216 may contact the second semiconductor chip 203 directly. Alternatively, the dummy wires 216 may contact the adhesive layer 205 on the bottom surface of the second semiconductor chip 203. Two or more dummy wires 216 may be positioned side-by-side in a horizontal direction z, depending on a level of support desired.

Dummy wires 216 may have various shapes and compositions. For example, a dummy wire 216 may have a arc shape, a flat tip portion, a pointed tip, a rounded tip. The dummy wire 216 may be composed of a metal wire material, a conductive wire material, or an insulation material. The dummy wire 216 may have elastic or non-elastic properties. It may be solid or a fiber material. It may be conductive but not electrically connected to the semiconductors 202, 203 or the substrate 201 of the semiconductor package 200.

FIGS. 2C and 2D illustrate stacked semiconductor packages 200 similar to those of FIGS. 2A and 2B, except the dummy wires 216 are arranged to run parallel to the horizontal direction x, and the dummy wires 216 contact the adhesive layer 205 on the lower side of the upper semiconductor chip 203.

As illustrated in FIGS. 2E-2G, the stacked semiconductor packages 200 illustrated in FIGS. 2A-2D may share a pad layout on the substrate 201. For example, FIG. 2E illustrates a substrate 201 having connection pads 208 formed at a first end to connect to connection pads 206 of the lower semiconductor chip 202. Connection pads 209 are formed at another end of the substrate 201 to connect to connection pads of the upper semiconductor chip (not shown in this figure).

Bonding pads 214 may be formed to be equidistant from each other, so that dummy wires 216 that are formed to be parallel to the direction x, as shown in FIG. 2F, and dummy wires 216 that are formed to be parallel to the direction z, as shown in FIG. 2G, may have a same length. In other words, the bonding pads 214 may be formed on the surface of the substrate 201 so that the distance d1 between the bonding pads 214 in the direction x is the same as the distances d2, d3 between the bonding pads in the direction z.

Alternatively, the distance d1 between the bonding pads 214 in the direction x may be different from either of the distances d2, d3 between the bonding pads 214 in the direction z. When the distance d1 between the bonding pads 214 in the direction x is different than the distance d2 between the bonding pads 214 in the direction z, then bonding wires 216 formed to be parallel to the direction x may have different lengths than bonding wires 216 formed to be parallel to the direction z. Consequently, the stacked semiconductor chip 200 having a single configuration of bonding pads 214 may be used to provide more than one level of resistance or support to an upper semiconductor chip.

For example, if the distance d1 is greater than the distance d2, then a dummy wire 216 formed between two bonding pads 214 to be parallel to the direction x would be longer than a bonding wire 216 formed between two bonding pads 214 to be parallel to the direction z. Consequently, the bonding wire 216 formed to be parallel to the direction x may provide less resistance, or a resistance over a larger area of the bottom surface of the upper semiconductor chip, than a dummy wire 216 formed between two bonding pads 214 to be parallel to the direction z.

FIGS. 2H and 2I illustrate dummy wires 216 having different lengths as a result of the bonding pads 214 being separated by different distances. In FIG. 2H, bonding pads 214 are separated by a distance d4. In FIG. 2I, the bonding pads 214 are separated by a distance d5 that is greater than the distance d4. As a result, the dummy wire 216 has a length longer than the dummy wire 216 of FIG. 2H. The dummy wires 216 may be formed to contact an underside of the upper semiconductor chip 203 along a length d6. Since the dummy wire 216 of FIG. 2I is longer than the dummy wire 216 of FIG. 2H, the dummy wire 216 of FIG. 2I may contact the underside of the upper semiconductor chip 203 along a longer length d6 than the dummy wire 216 of FIG. 2G is able to do.

In addition, as illustrated in FIGS. 2H and 2I, since a shorter dummy wire 216 of FIG. 2H may extend from the bonding pad 214 at a higher angle θ1 than the angle θ2 of the longer dummy wire 216 of FIG. 2I, the shorter dummy wire 216 of FIG. 2H may provide a greater resistance, or a stiffer support, than the longer dummy wire 216 of FIG. 2I.

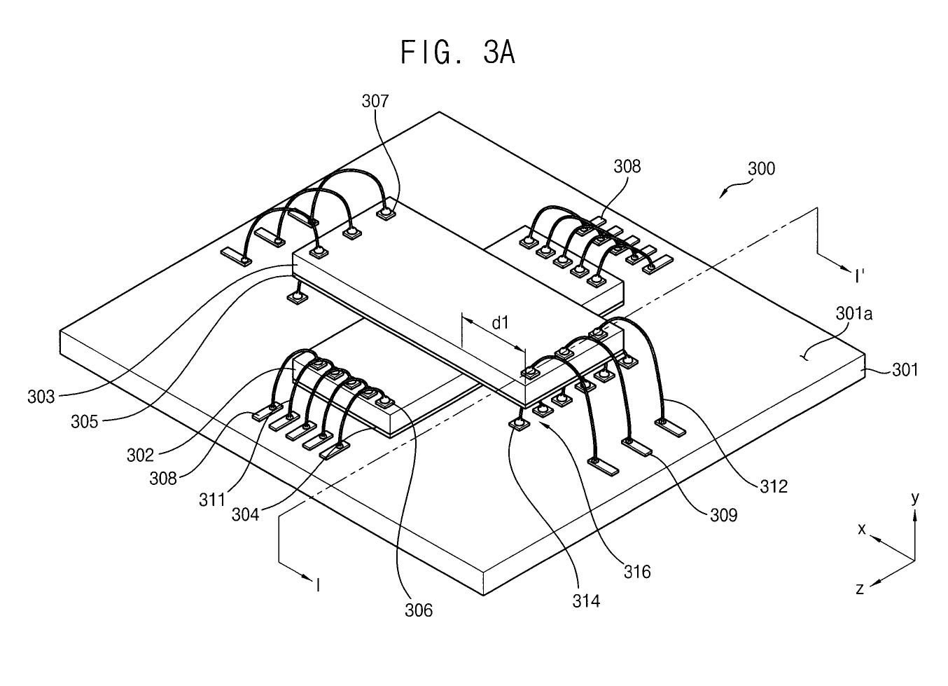

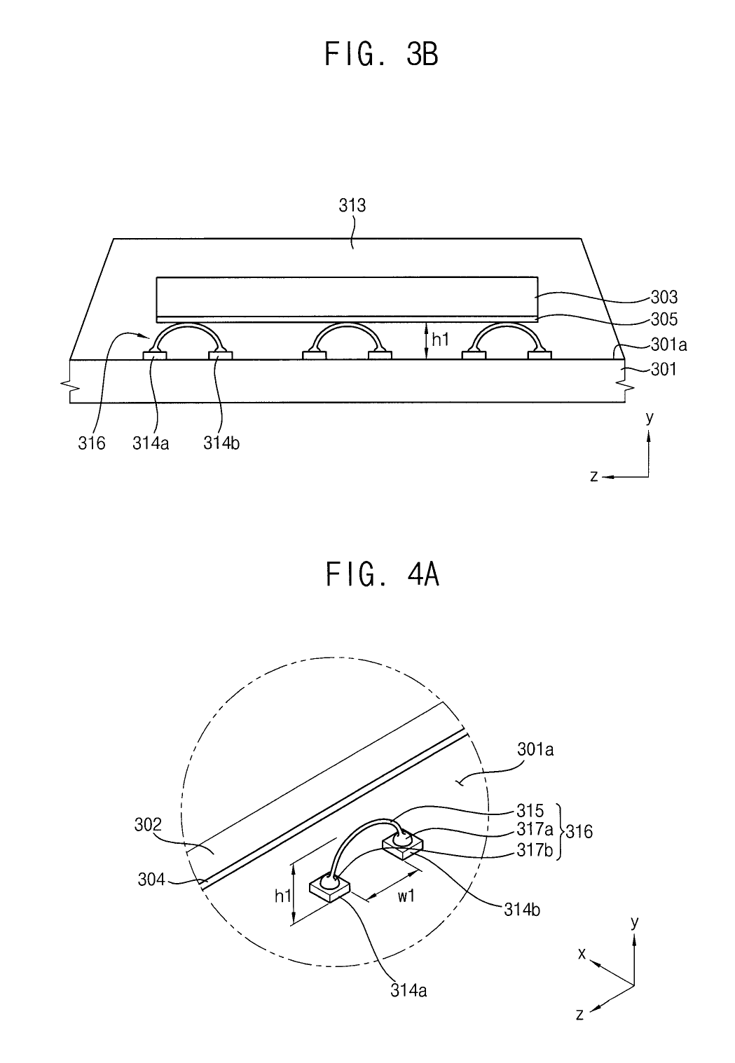

FIGS. 3A and 3B illustrate another embodiment of a stacked semiconductor package 300 according to the general inventive concept. As illustrated in FIG. 3A, the stacked semiconductor package 300 may include a substrate 301, a first semiconductor chip 302 mounted on an upper surface 301a of the substrate 301, and a second semiconductor chip 303 mounted on the first semiconductor chip 302. The second semiconductor chip 303 may be oriented at ninety degrees with respect to the first semiconductor chip 302 so that a center of the second semiconductor chip 303 is located over the center of the first semiconductor chip 302 and the ends of the second semiconductor chip 303 are located above the substrate 301. Alternatively, the second semiconductor chip 303 may be oriented at any other angle with respect to the first semiconductor chip 301.

As with the stacked semiconductor package of FIGS. 2A and 2B, the stacked semiconductor package 300 of FIGS. 3A and 3B may include the substrate 301 and bonding pads 308, 309 on an upper surface 301a of the substrate 301 to receive wires 311, 312 connected to bonding pads 306, 306 of the first and second semiconductor chips 302, 303, respectively. The semiconductor chips 302, 303 may include memory devices, such as DRAM, PRAM, and Flash Memory, or any other semiconductor chip, including logic circuitry, etc. In addition, adhesive layers 304, 305 may bond the semiconductor chips 302, 303 to each other and to the substrate 301.

The adhesive layers 304, 305 may include epoxy paste and epoxy tape, for example. The adhesive layers may be insulators or they may have conductive properties to conduct heat or electricity. The adhesive layers 304, 305 may be replaced by, or used with, wiring layers (not shown) to connect the semiconductor chips 302, 303 to each other and to the substrate 301.

Bonding pads 314 may be formed beneath an overhanging portion of the second semiconductor chip 303 and dummy wires 316 may be formed to connect adjacent bonding pads 314. The entire stacked semiconductor package may be encased in a mold 313, as illustrated in FIG. 3B.

As mentioned previously, the second semiconductor chip 303 may be rotated ninety degrees with respect to the first semiconductor chip 302 and mounted to the first semiconductor chip 302. As a result, a portion of the second semiconductor chip 303 may extend past an edge of the first semiconductor chip 302 in a horizontal direction x. The overhanging portion may overhang past the edge of the first semiconductor chip 302 by a distance d1.

FIG. 3B illustrates a cross-sectional view of the stacked semiconductor package of FIG. 3A along the line I-I′. As illustrated in FIG. 3B, multiple dummy wires 316 may be positioned in a horizontal direction z beneath the overhang portion of the second semiconductor chip 303. The number of dummy wires 316 used may be determined based on a desired level of support, a strength of the semiconductor chip 303 and the adhesives 304, 305, available space on the substrate 301, time to form the dummy wires 316, and cost to produce additional dummy wires 316. The distance d1 that the second semiconductor chip 303 extends past the side of the first semiconductor chip 302 may be used to determine a desired number of dummy wires 316.

The dummy wires 316 may extend between two bonding pads 314a, 314b. The dummy wires 316 and bonding pads 314 may have a combined height h1 sufficient to allow the dummy wires 316 to contact and support the bottom surface of the second semiconductor chip 303.

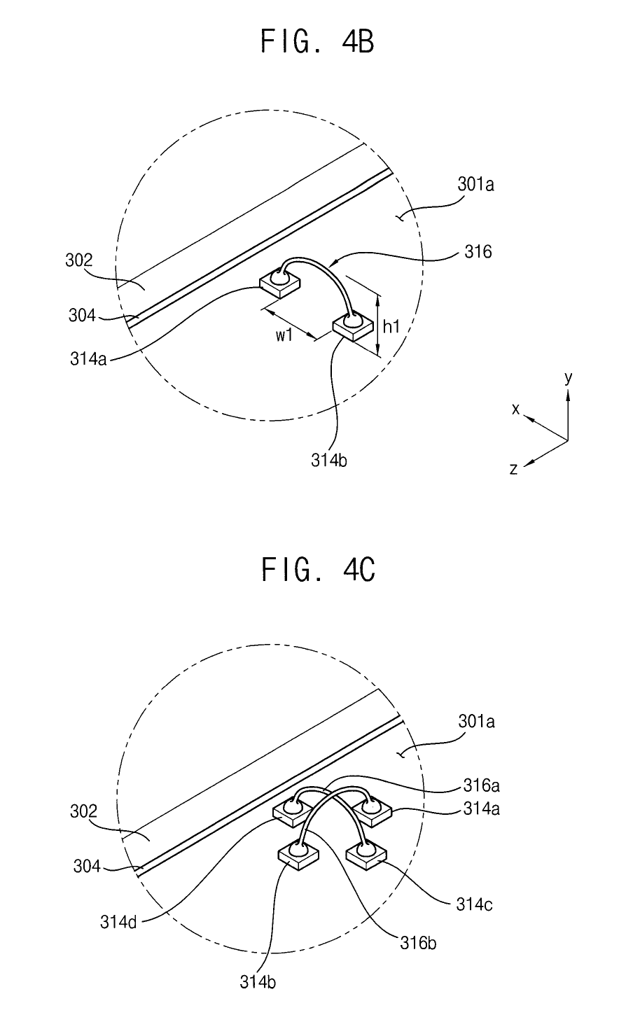

FIGS. 4A-4C illustrate three different configurations of the dummy wires.

In FIG. 4A, a dummy wire 316 is positioned on the upper surface 301a of the substrate 301 adjacent to a side of the first semiconductor chip 302 and the adhesive layer 304 in a horizontal direction x. An imaginary plane passing through the center of the length of the dummy wire 316 is parallel to the adjacent side surface of the first semiconductor chip 302. In other words, the bonding pads 314a, 314b are positioned in the horizontal direction z with respect to each other, and the dummy wire 316 connected to the bonding pads 314a, 314b extends in the horizontal direction z to be connected to the bonding pads 314a, 314b.

The bonding pads 314a, 314b are separated by a predetermined distance w1. The distance between the first pad 314a and the second pad 314b and the distance between the pads 314a, 314b and the bottom surface of the second semiconductor chip 303 determine a length and shape of a corresponding dummy wire 316. For example, the bonding pads 314a, 314b may be positioned closer to each other to cause the dummy wire 316 to provide a greater physical resistance or stiffness, or they may be positioned farther apart from each other to cause the dummy wire 316 to have a lesser physical resistance.

The dummy pads may be formed of any appropriate material and may be affixed to the upper surface 301a of the substrate 301 by an adhesive, such as epoxy or polyimide film, for example.

Each dummy wire 316 may include first and second end portions 317a, 317b and a center wire portion 315. The dummy wire 316 may have a thickness greater than a functional conductive wire, such as wires 311 and 312 of FIGS. 3A and 3B. The dummy wire may be formed of any appropriate material. For example, the dummy wire 316 may be formed of the same material and in the same manufacturing process as the functional wire 311 of FIG. 3A. Alternatively, the dummy wire 316 may be formed of a non-conductive material.

As illustrated in FIG. 4B, the dummy wire 316 may be oriented in a direction other than the direction z. FIG. 4B illustrates the dummy wire 316 oriented in the horizontal direction x, perpendicular to the direction z. FIG. 4C illustrates a first, lower dummy wire 316a oriented in the direction x and a second, upper dummy wire 316b oriented in the direction z. This configuration may allow the lower dummy wire 316a to provide additional support to the upper dummy wire 316b and to overhang portion of the second semiconductor chip 303.

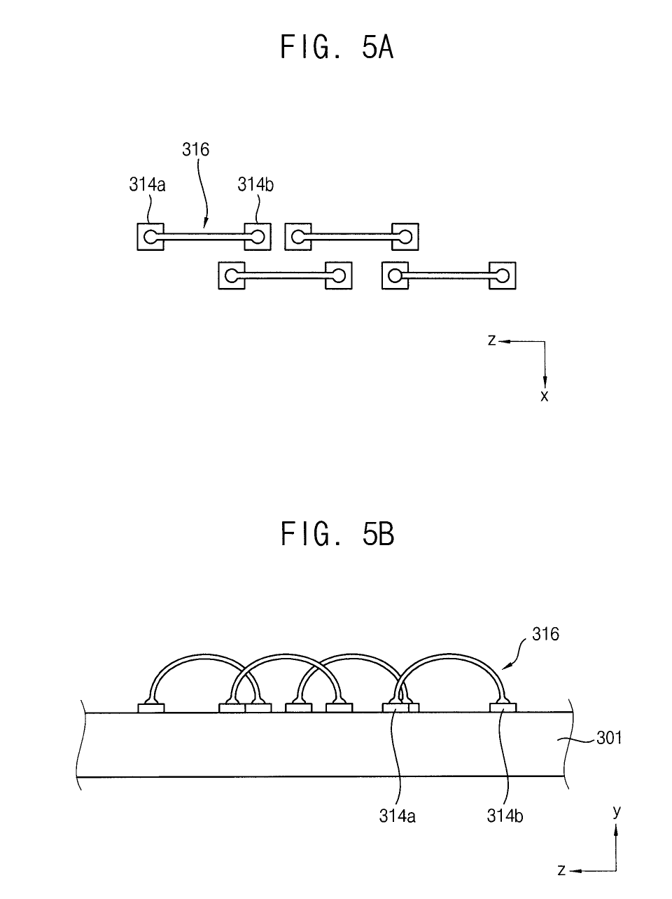

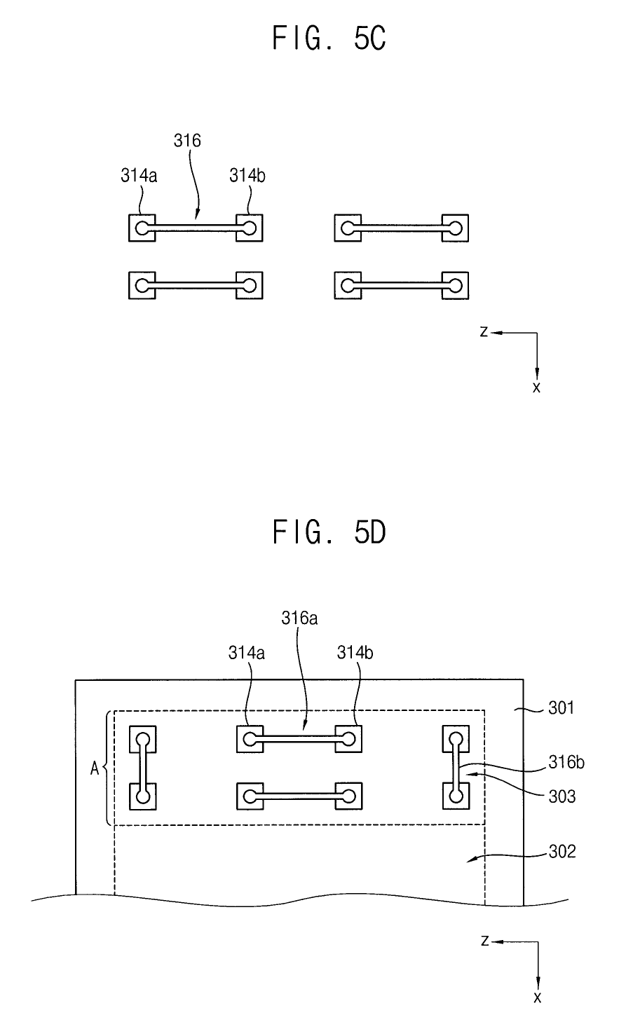

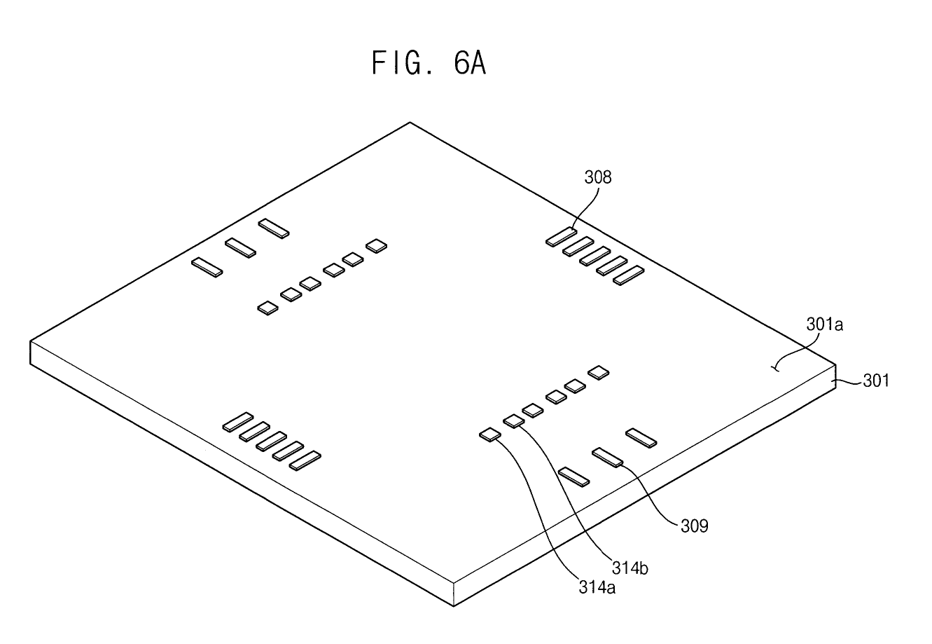

While the embodiments described thus far have illustrated multiple dummy wires 316 arranged in a line, the dummy wires 316 may be configured in any appropriate manner. FIGS. 5A-5D illustrate various configurations of the dummy wires 316.

In FIGS. 5A and 5B, a plurality of dummy wires 316 is arranged in a plurality of rows. One row is offset from the other in the direction x so that a peak of a wire from one row corresponds to a position on the bottom surface of the second semiconductor chip 303 different than the position of a peak of a wire from the other row.

FIG. 5C illustrates an alternative configuration in which multiple bonding pads 314a, 314b are arranged in rows and columns, in the horizontal directions x, z, so that the peaks of each dummy wire 316 correspond to the peak of each other dummy wire 316 in the same row and column.

FIG. 5D illustrates a configuration in which dummy wires 316 are aligned in different directions from one another. A first dummy wire 316a extends parallel to the horizontal direction z, and a second dummy wire 316b extends parallel to the horizontal direction x, which is perpendicular to the direction z. Each dummy wire 316a, 316b may extend in a direction parallel to an adjacent side of the second semiconductor chip 303. For example, the dummy wire 316a extends in the direction z and is adjacent to a side of the second semiconductor chip 303 that also extends in the direction z. Likewise, the dummy wire 316b extends in the direction x and is adjacent to a side of the semiconductor chip 303 that also extends in the direction x.

While a few example configurations of dummy wires 316 have been illustrated above, one of ordinary skill in the art may configure the dummy wires 316 as needed to provide a desired support, footprint, and cost.

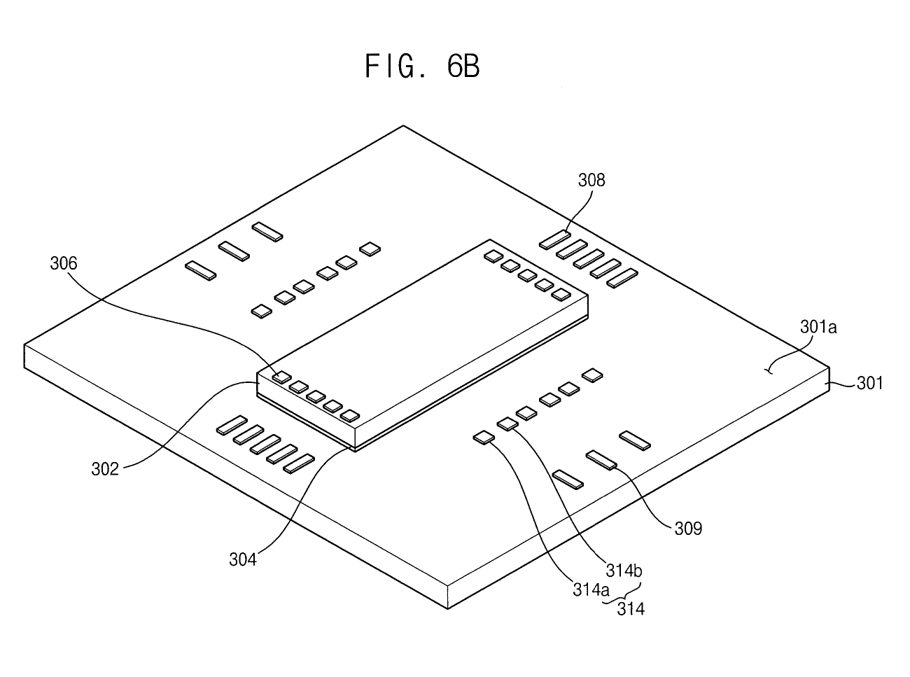

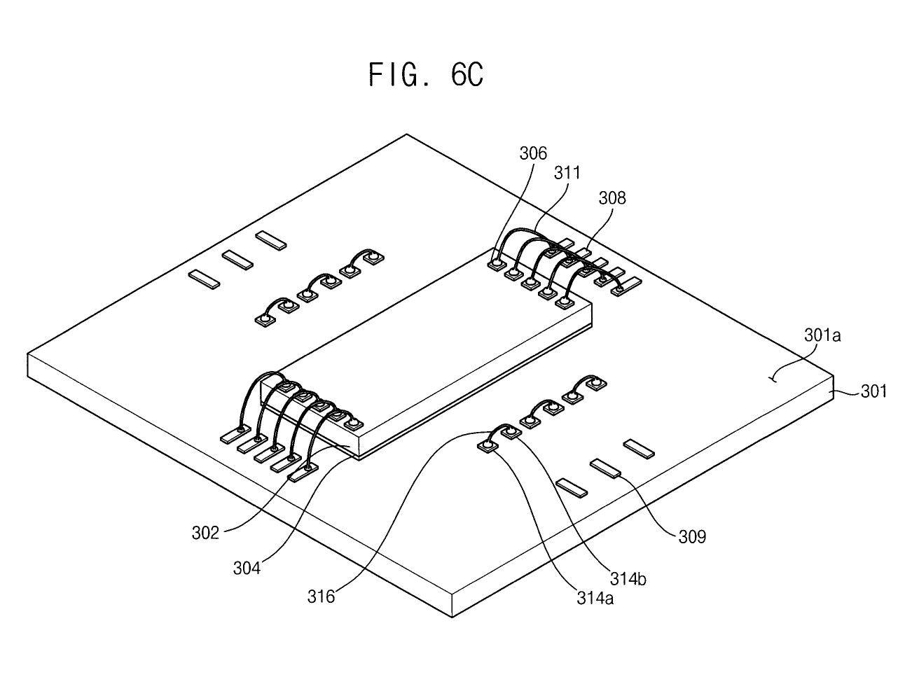

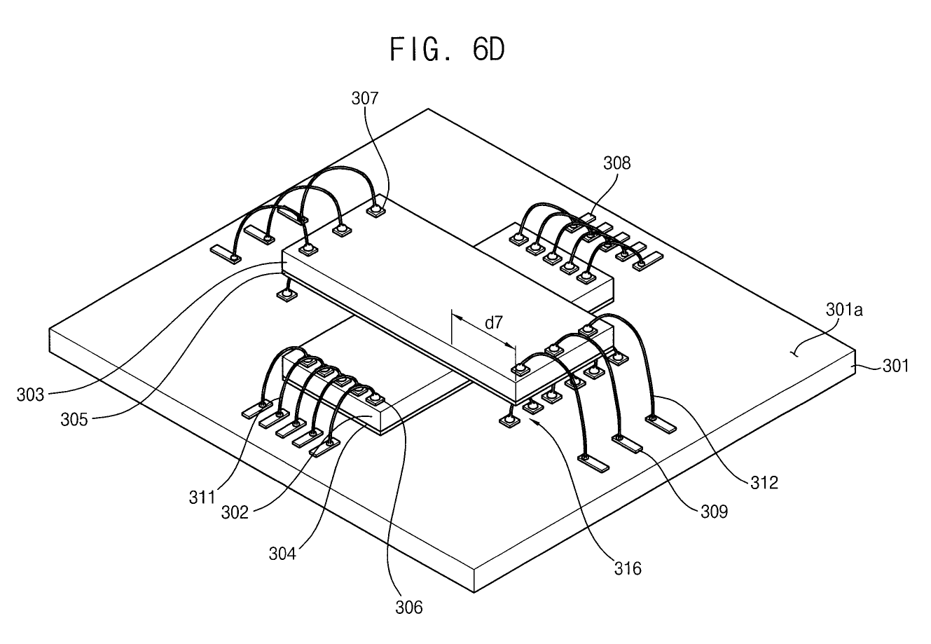

FIGS. 6A-6D illustrate a method of manufacturing the stacked semiconductor chip 300 of FIG. 3A. First, a substrate 301 is provided and bonding pads 308, 309 are formed on the upper surface 301a of the substrate 301. The bonding pads 308, 309 may be connected to circuitry within the substrate 301 to connect the upper surface 301a to a bottom surface (not shown) opposite the upper surface. Bonding pads 314 for dummy wires 316 may be formed in the same process as the bonding pads 308, 309 or in a separate process. The bonding pads 314 may be of the same material or of a different material as bonding pads 308, 309.

Next, as illustrated in FIG. 6B, a first semiconductor chip 302 may be affixed to the upper surface 301a of the substrate 301 with an adhesive 304. The first semiconductor chip 302 may have bonding pads 306 on an end of an upper surface and the bonding pads 306 may correspond to the bonding pads 308 on the substrate 301a, so that the sides of the semiconductor chip 302 are adjacent to the dummy wire bonding pads 314 and the ends of the semiconductor chip 302 are adjacent to the substrate bonding pads 308.

Next, as illustrated in FIG. 6C, conductive wires 311 are connected between the bonding pads 306 of the upper surface of the first semiconductor chip 303 and the bonding pads 308 on the upper surface 301a of the substrate 301. In addition, dummy wires 316 are formed between adjacent dummy contact pads 314a, 314b. The dummy wires 316 may be formed in the same process as the functional wires 311 and may be formed of the same material as the functional wires 311. Alternatively, the dummy wires 316 may be formed in a different manufacturing process or step and may be formed of different materials than the wires 311.

Finally, as illustrated in FIG. 6D, a second semiconductor chip 303 is mounted on the upper surface of the first semiconductor chip 302 with an adhesive layer 305, and wires are formed to connect bonding pads 307 of the second semiconductor chip 303 with the bonding pads 309 of the upper surface 301a of the substrate. The second semiconductor chip 303 may be oriented at a ninety degree angle with respect to the first semiconductor chip 302 so that portions of the second semiconductor chip 303 corresponding to the overhang distance d7 extend past an edge of the first semiconductor chip 302. The portion of the second semiconductor chip 303 that extends past an end of the first semiconductor chip 302 corresponds to the location of the dummy wires 316, so that the dummy wires 316 may provide support to the overhang portion.

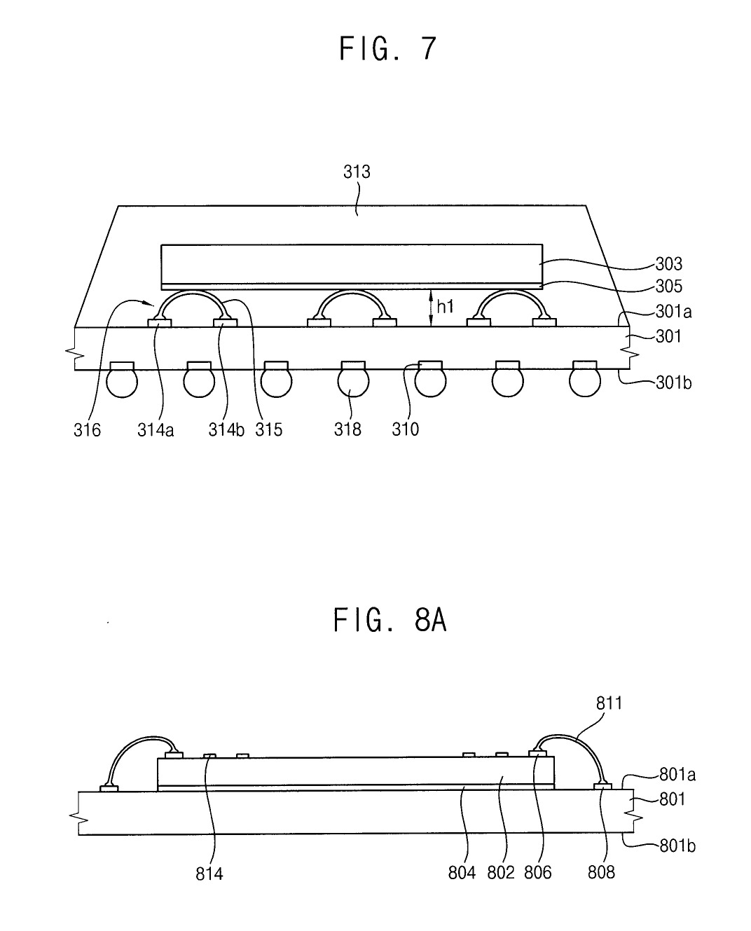

In addition, as shown in FIG. 7, additional manufacturing operations may be included to encase the semiconductor chips 302, 303 and wires 311, 312, 314 in a molding material to provide insulation. Also, solder balls 318 may be formed on bonding pads 310 located on a bottom surface 301b of the substrate 301 to connect the stacked semiconductor package 300 to an adjacent device.

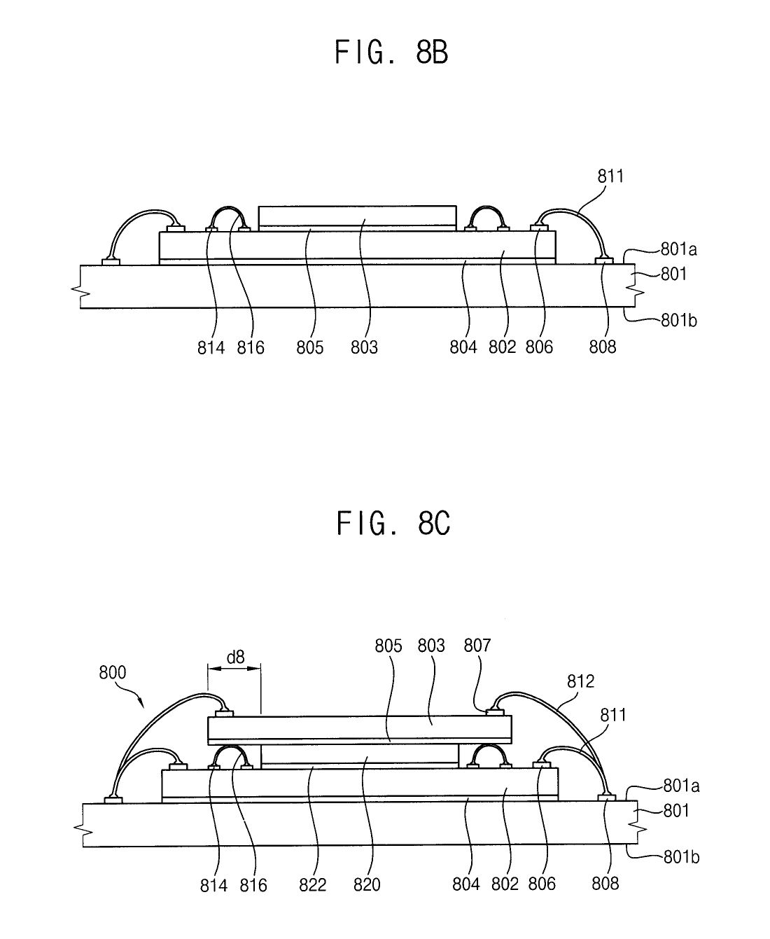

FIGS. 8A-8C illustrate a stacked semiconductor package 800 and a method of manufacturing the semiconductor package 800 according to another embodiment of the present general inventive concept.

In FIG. 8A, a substrate 801 having an upper side 801a and a bottom side 801b is provided. The substrate may have bonding pads 808 located on its upper surface 801a. A first semiconductor chip 802 is affixed to the upper surface 801a of the substrate 801 with an adhesive layer 804. The substrate has bonding pads 806 located on its upper surface, and a wire 811 is formed to connected the bonding pads 806 of the first semiconductor chip 802 with the bonding pads 808 of the substrate 801. The first semiconductor chip 802 also has bonding pads 814 on its upper surface to mount a dummy wire 816.

In FIG. 8B, an intermediate semiconductor chip 820 is mounted onto the first semiconductor chip 802 via an adhesive 822 and dummy wires 816 may be formed between the bonding pads 814. FIG. 8C illustrates a second semiconductor chip 803 mounted on the intermediate chip 820 via an adhesive layer 805. The second semiconductor chip 803 extends past an edge of the intermediate chip 820 by a distance d8, so that a bottom surface of the second semiconductor chip 803, or the adhesive layer 805 on the bottom surface, contacts and is supported by the dummy wire 816. The second semiconductor chip 803 includes bonding pads 807 on its upper surface, and wires are formed to connect the bonding pads 807 to the bonding pads 808 of the substrate 801.

According to the embodiment illustrated in FIG. 8C, the intermediate semiconductor chip 820 may be electrically connected to the first and second semiconductor chips 802, 803 via wiring layers, pads, or redistribution layers (not shown) on the same level as the adhesive layers 805, 822. The intermediate semiconductor chip 820 may transmit data, power, and/or heat to the first and second semiconductor chips 802, 803, or it may serve as an electrical, physical, and/or thermal buffer.

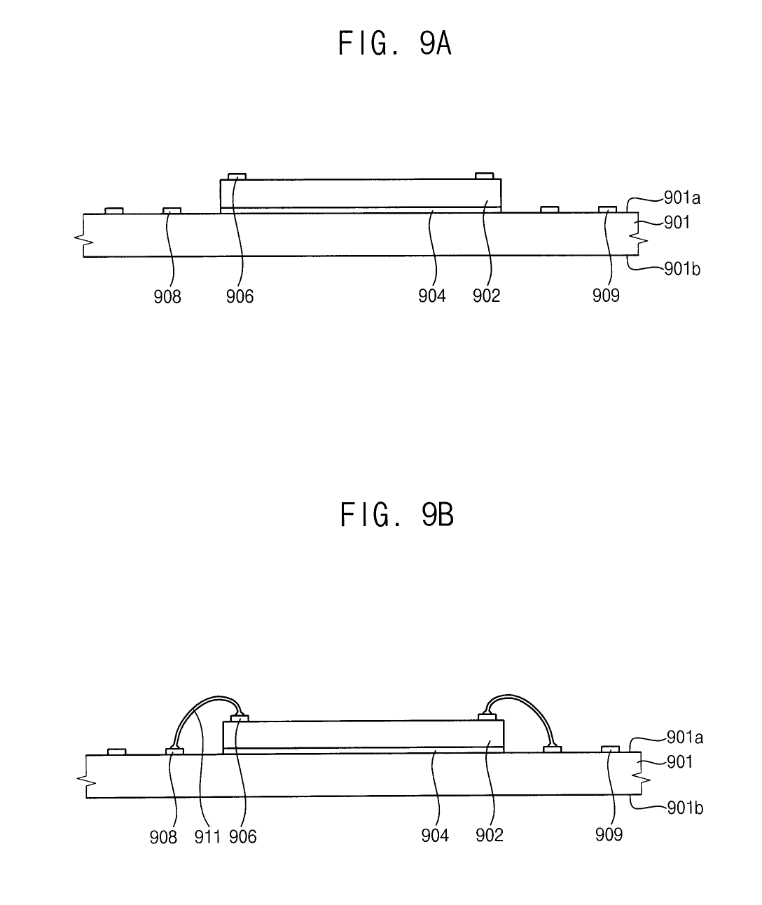

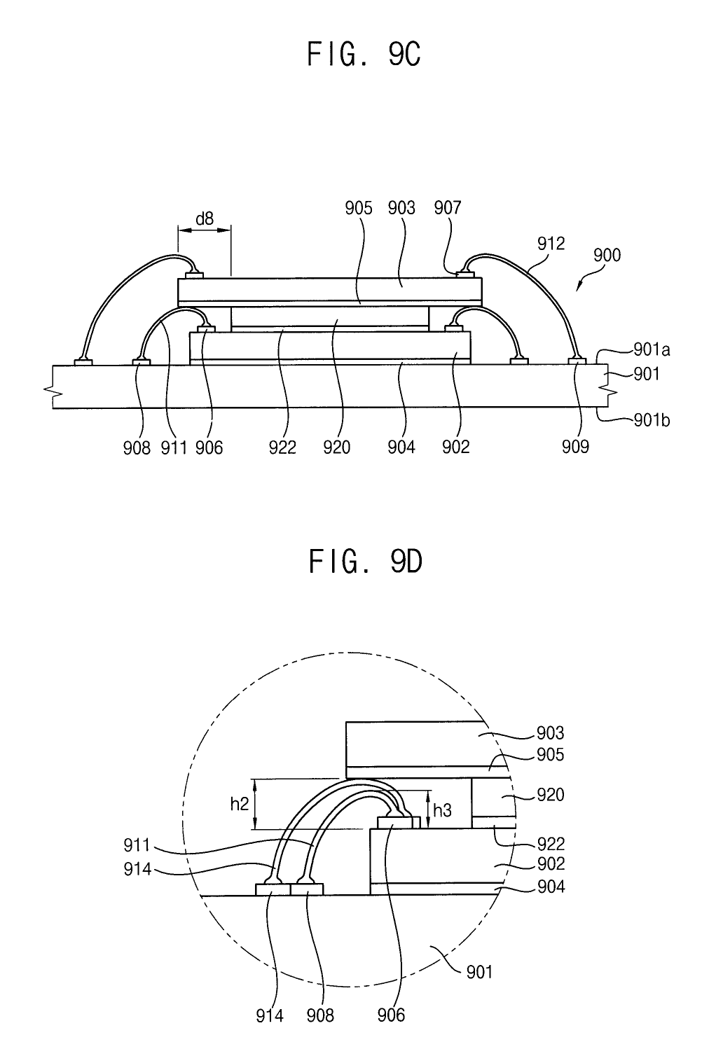

FIGS. 9A-9D illustrate a method of forming a stacked semiconductor package 900 similar to that of FIGS. 8A-8C but without the dummy wires on the first semiconductor chip.

Specifically, in FIG. 9A, a first semiconductor chip 902 is mounted onto an upper surface 901a of a substrate 901 via an adhesive layer 904. The substrate may have inner bonding pads 908 to receive a wire from the first semiconductor chip 902 and outer bonding pads 909 to receive a wire from a second semiconductor chip 903. The first semiconductor chip 902 has bonding pads 906 around the edges of its upper surface.

FIG. 9B illustrates forming wires 911 between the bonding pads 906 of the first semiconductor chip 902 and the bonding pads 908 of the substrate.

FIG. 9C illustrates mounting an intermediate semiconductor chip 920 onto a central portion of the first semiconductor chip 902 via an adhesive layer 922 and mounting a second semiconductor chip 903 onto the intermediate semiconductor chip 920 via an adhesive layer 905. A wire 912 connects a bonding pad on the upper surface of the second semiconductor chip 903 with a bonding pad 909 on the upper surface 901a of the substrate 901. An end portion of the second semiconductor chip 903 extends past a side edge of the intermediate chip 920 by a distance d8. The wire 911 is formed at such a height as to contact the bottom surface, or the adhesive layer 905, of the second semiconductor chip 903.

By utilizing this method, a separate dummy wire need not be manufactured, and the pre-existing functional wires may provide physical support to the overhang portion of the second semiconductor chip 903. The functional wires may have a size that is similar to other functional wires, or they may have a thickness greater than standard functional wires.

While the wire 911 may be a functional wire, at least one dummy wire may also be connected between a bonding pad 906 of the first semiconductor chip 902 and a bonding pad 908 on the substrate 901. In addition, wires of differing heights may be used.

As illustrated in FIG. 9D, a functional wire 911 and a dummy wire 914 may each be connected to adjacent bonding pads 906 on the first semiconductor chip 902. Alternatively, the respective wires 911, 914 may be connected to bonding pads that are offset from each other, such as bonding pads 908, 914 on the substrate. The dummy wire 916 may be formed at a height h2 that is greater than the height h3 of the functional wire 911. By this method of manufacturing, separate sets of bonding pads need not be formed for the dummy wires, but the functional wires may still be protected from physical strain or deformation.

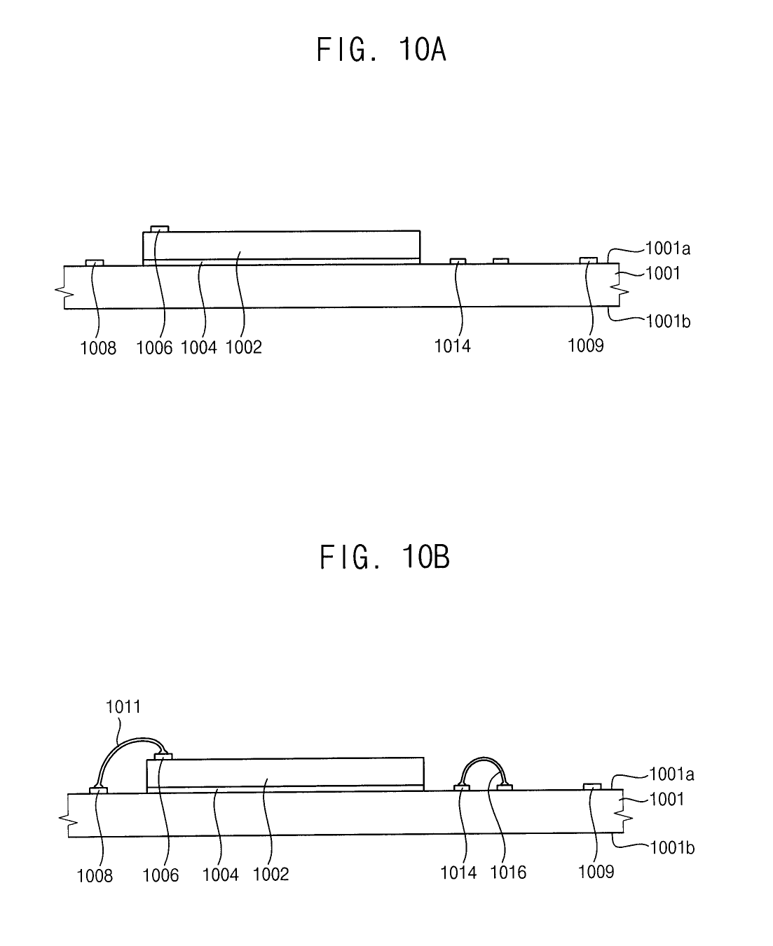

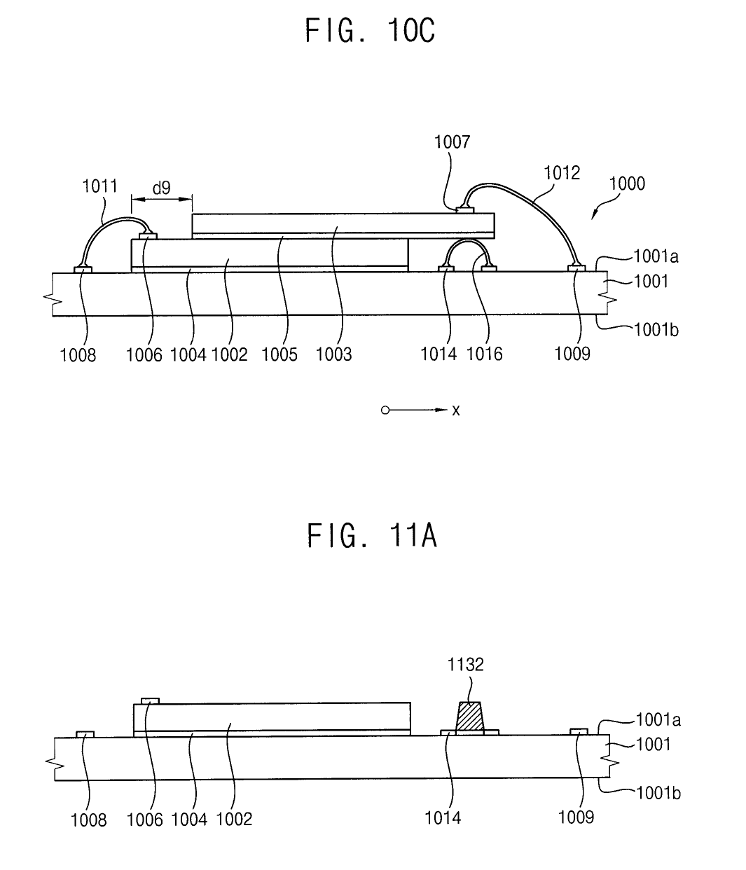

FIGS. 10A-10C illustrate a stacked semiconductor package 1000 and a method of manufacturing the same according to another embodiment of the present general inventive concept.

FIG. 10A illustrates a first semiconductor chip 1002 mounted on an upper surface 1001a of a substrate 1001 via an adhesive layer 1003. The substrate has first and second bonding pads 1008, 1009 and dummy bonding pads 1014. The dummy bonding pads 1014 are to bond dummy wires 1016 and may be either conductive or non-conductive pads. The first semiconductor chip 1002 has bonding pads 1006 located on an upper surface.

FIG. 10B illustrates forming functional wires 1011 between the bonding pads of the first semiconductor chip 1002 and the bonding pads 1008 of the substrate 1001. Dummy wires 1016 may also be formed in the same manufacturing operation or in a different operation. The dummy wires 1016 are formed between two bonding pads 1014 on the substrate 1001.

FIG. 10C illustrates mounting a second semiconductor chip 1003 to the first semiconductor chip 1002 via an adhesive layer 1005. The second semiconductor chip 1003 is offset from the end of the first semiconductor chip 1002 by a distance d9 in the direction x, so that the bonding pad 1006 of the first semiconductor chip 1002 is exposed and the second semiconductor chip 1003 extends past an end of the first semiconductor chip 1002. The portion of the second semiconductor chip 1003 that extends past the end of the first semiconductor chip 1002 may correspond to the location of the dummy wires 1016 so that the dummy wires 1016 support the under-side of the second semiconductor chip 1003. A wire 1012 is formed to connect a bonding pad 1007 on the upper surface of the second semiconductor chip 1003 with a bonding pad 1009 on the substrate 1001.

The semiconductor package 1000 of FIG. 10C is similar to the semiconductor package illustrated in FIG. 2A, except in FIG. 2A the dummy wires 216 are aligned parallel to the horizontal direction z and in FIG. 10C the dummy wires 1016 are aligned parallel to the horizontal direction x.

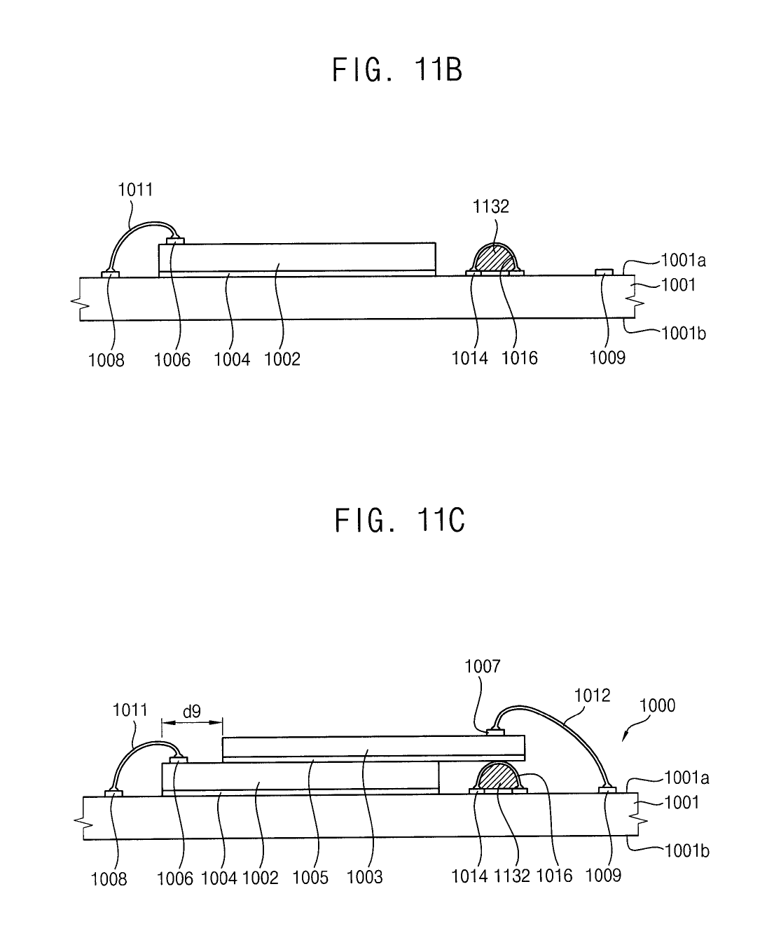

FIGS. 11A-11C illustrate a method of forming a semiconductor package 1000 similar to that of FIGS. 10A-10C. However, as illustrated in FIG. 11A, a polymer material 1132 may be formed on or between the bonding pads 1014. FIG. 11B illustrates a dummy wire 1016 being formed on the polymer material. When the second semiconductor chip 1003 is mounted on the first semiconductor chip 1002, and the overhang portion contacts the dummy wire 1016, the polymer material 1132 may provide additional support to the dummy wire 1016.

The polymer material 1132 may include underfill material, elastic memory composite (EMC) material, adhesive, or any other appropriate supporting material. In addition, the polymer material 1132 may be formed on the substrate 1001 either before or after the dummy wire 1016 is formed.

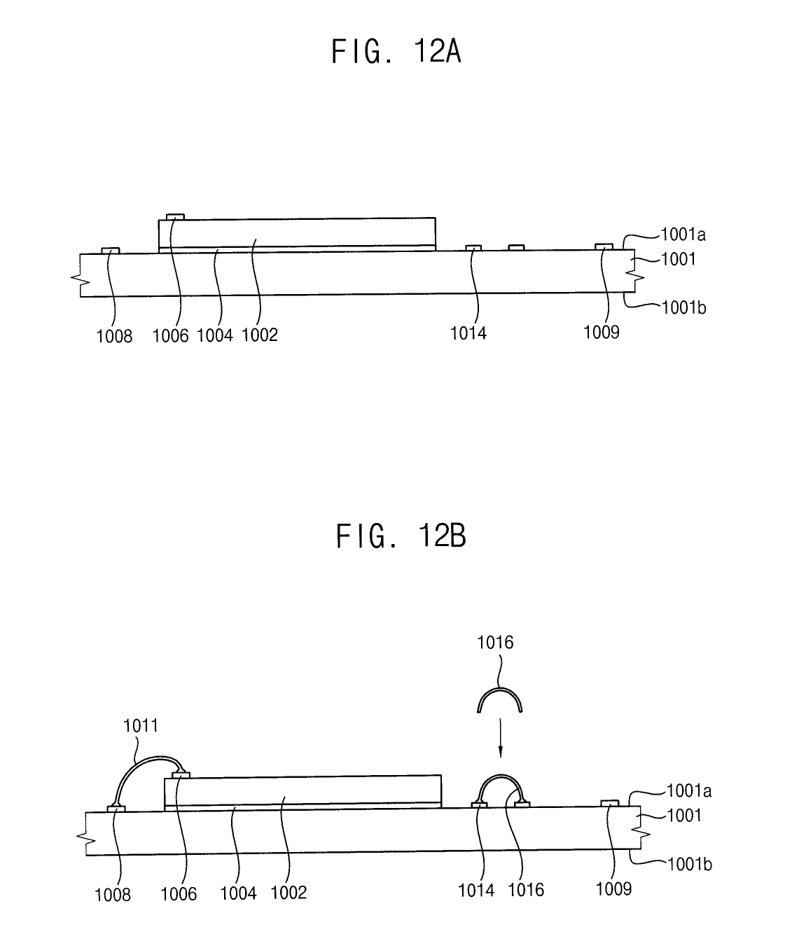

As illustrated in FIGS. 12A-12C, the dummy wire 1016 may be pre-formed or pre-shaped and then bonded to the bonding pads 1014 with a solder paste, polymer adhesive, or other bonding agent.

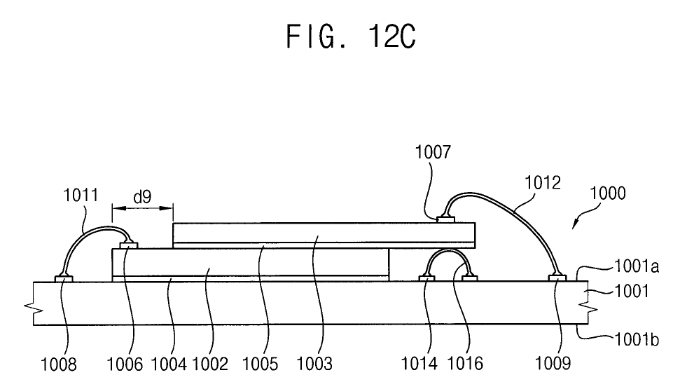

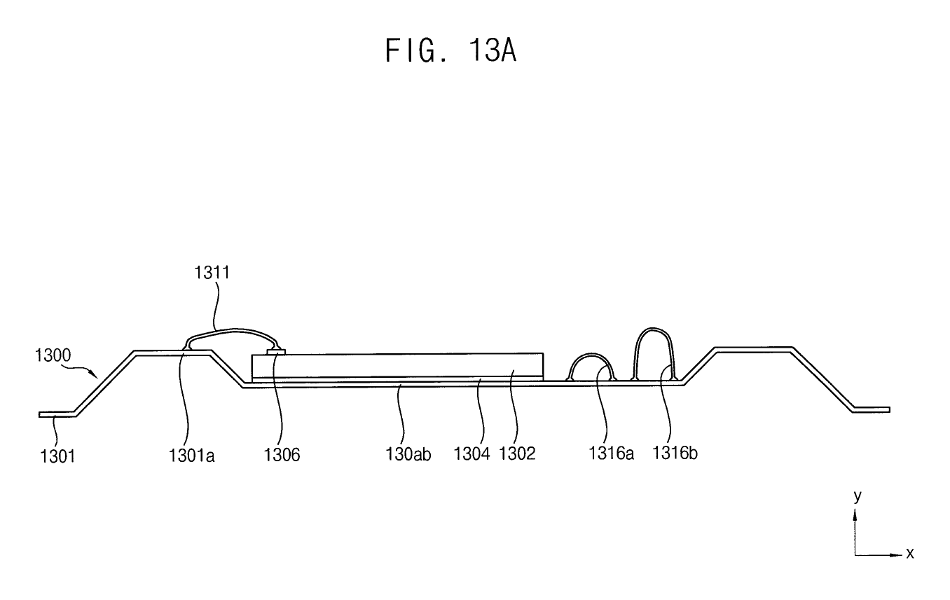

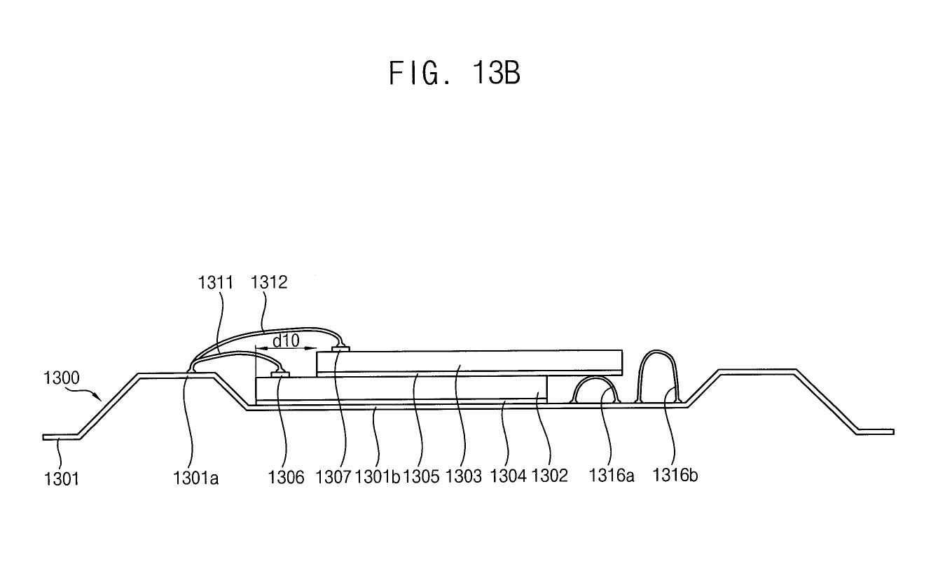

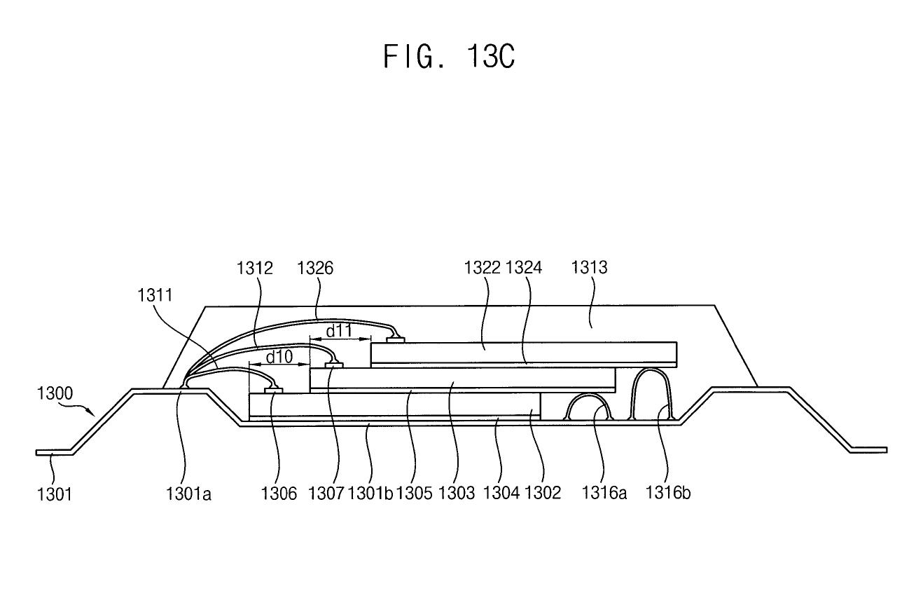

FIGS. 13A-13 illustrate a stacked semiconductor package 1300 and a method of forming the same according to another embodiment of the present general inventive concept.

FIG. 13A illustrates a first semiconductor chip 1302 mounted on a shaped substrate or frame 1301 via an adhesive layer 1303. The frame 1301 may include a recessed portion 1301b to receive the first semiconductor chip 1302 and raised portions 1301a surrounding the recessed portion 1301b. The frame 1301 may have any desired shape, however.

A wire 1311 may connect a bonding pad 1306 of the first semiconductor chip 1302 with a bonding pad or lead (not shown) of the frame 1301. Dummy wires 1316a, 1316b may also be formed in the recessed portion 1301b of the frame 1301. The dummy wires 1316a, 1316b may be formed to have peaks of varying heights in the vertical direction y to correspond to semiconductor chips at differing elevations. The dummy wires 1316a, 1316b may also be positioned at varying distances in the horizontal direction x to correspond to differing locations of overhangs of stacked semiconductor chips.

As illustrated in FIG. 13B, a second semiconductor chip 1303 is mounted to the upper surface of the first semiconductor chip 1302 via an adhesive layer 1305. The second semiconductor chip 1303 is offset from the first semiconductor chip 1302 in the horizontal direction x by a distance d10. This offset allows the bonding pad 1306 of the first semiconductor chip 1302 to remain exposed. A portion of the second semiconductor chip 1303 extends past the end of the first semiconductor chip 1302, so that the first dummy wire 1316a supports a bottom surface of the second semiconductor chip 1303 via the adhesive layer 1305. The offset distance d10 of the second semiconductor chip and the location of the second dummy wire 1316b may be adjusted so that the second semiconductor chip does not contact the second dummy wire 1316b. A functional wire 1312 may be formed between a bonding pad 1307 of the second semiconductor chip 1303 and a bonding pad or lead (not shown) of the frame 1301.

As illustrated in FIG. 13C, a third semiconductor chip 1322 is mounted to the upper surface of the second semiconductor chip 1303 via an adhesive layer 1324. The third semiconductor chip 1322 is offset from the second semiconductor chip 1303 in the horizontal direction x by a distance d11. A portion of the third semiconductor chip 1322 extends past the end of the second semiconductor chip 1303, so that the second dummy wire 1316b supports a bottom surface of the third semiconductor chip 1322 via the adhesive layer 1324. A wire 1326 may be formed between a bonding pad 1330 on the top surface of the third semiconductor chip 1322 and a bonding pad or lead (not shown) of the frame 1301.

A molding material 1313 may be formed around the semiconductor chips 1302, 1303, and 1322 and the wires 1311, 1312, 1326, and 1316 to encapsulate the stacked semiconductor package 1300.

While the above embodiment refers to a frame, any appropriate substrate may be used. In addition, the stacked semiconductor packages may include any number of stacked semiconductor chips depending on desired structure, space, and performance.

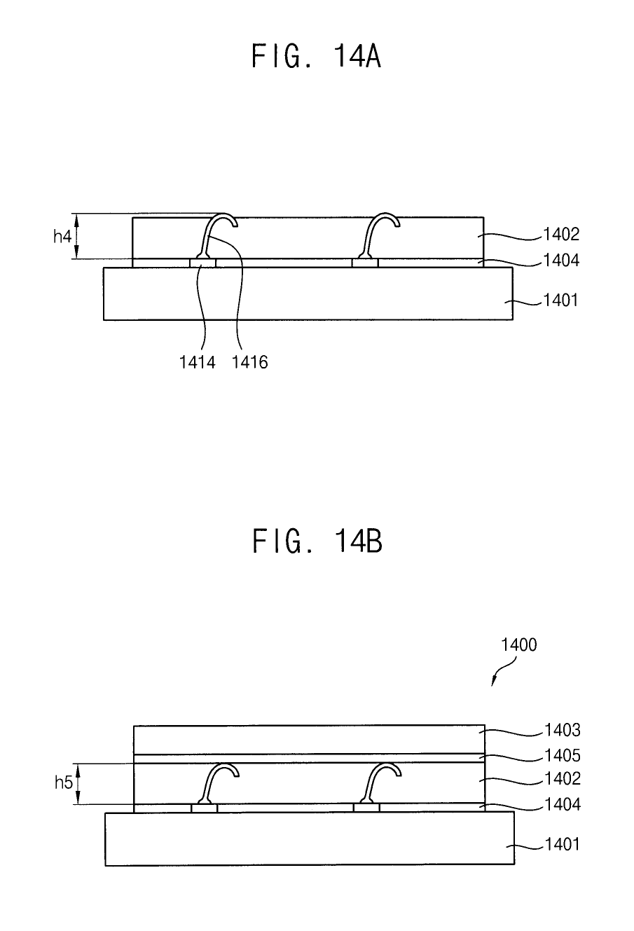

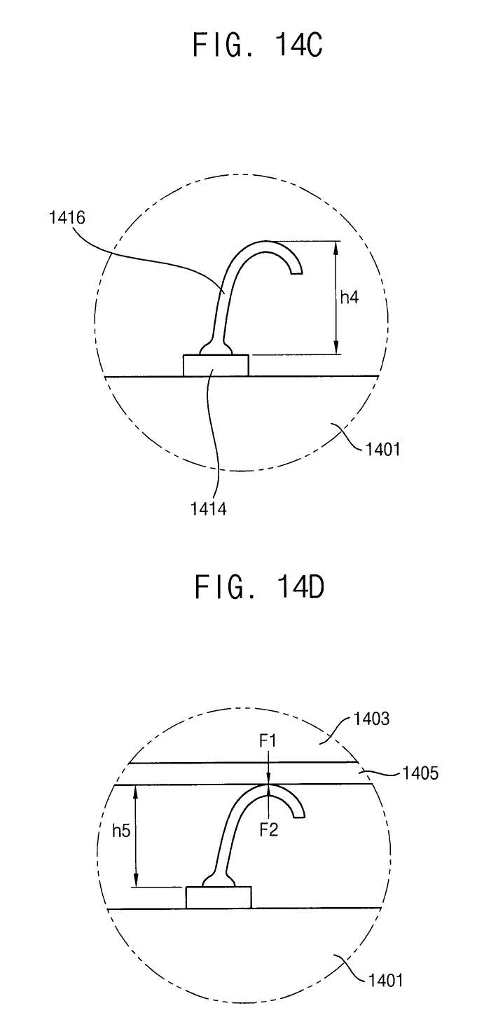

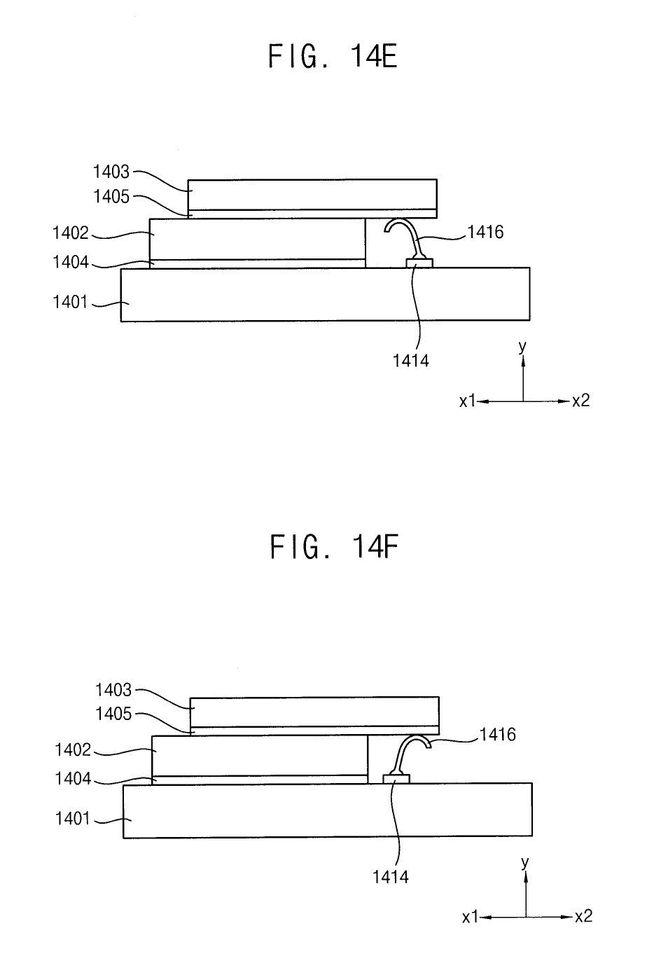

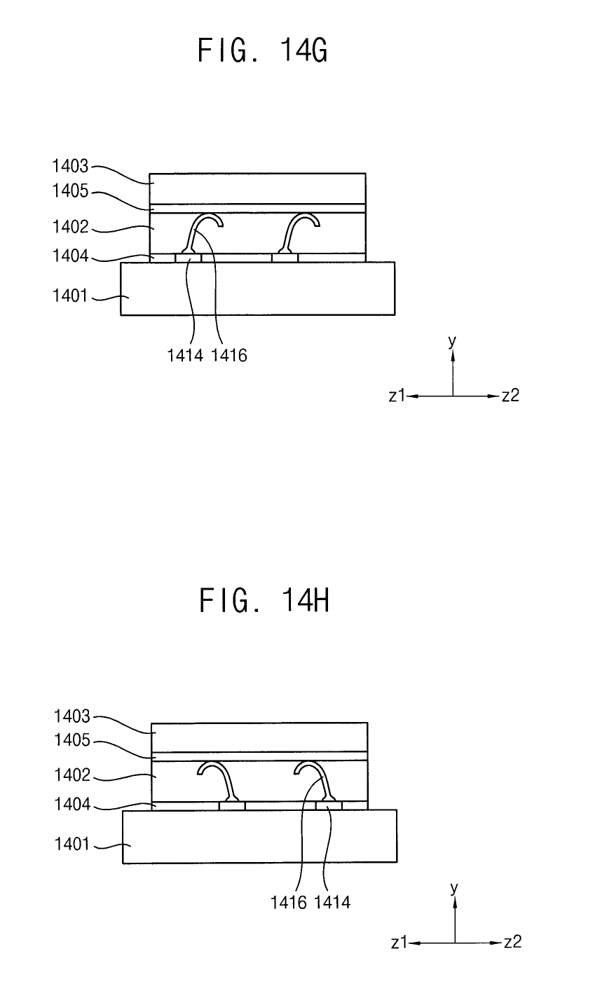

FIGS. 14A-14E illustrate a stacked semiconductor package 1400 according to another embodiment of the present general inventive concept. As illustrated in FIGS. 14A and 14B, the configuration of the stacked semiconductor package 1400 may be similar to any one of FIGS. 2A-13C, except the dummy wire 1416 may be connected to only one bonding pad 1414. The stacked semiconductor package 1400 may include a substrate 1401, a lower semiconductor chip 1402 mounted to the substrate 1401 via an adhesive layer 1404, connection pads 1414, and dummy wires 1416.

FIG. 14A illustrates dummy wires 1416 formed on bonding pads 1414 adjacent to the lower semiconductor chip 1402. The dummy wires 1416 may be connected at one end to bonding pads 1414, and the other end of the dummy wires 1416 may be disconnected. The dummy wires 1416 may be formed in a shape of an arch with an apex that contacts the underside of an upper semiconductor chip 1403. The dummy wire 1416 may have a height h4 before the upper semiconductor chip 1403 is mounted onto the lower semiconductor chip 1402. As illustrated in FIGS. 14B-14D, once the upper semiconductor chip 1403 is mounted onto the lower semiconductor chip 1402 via an adhesive layer 1405, the upper semiconductor chip 1403 may exert a force, represented by the reference letter F1, onto the dummy wire 1416 to deform the dummy wire. As a result, the dummy wire 1416 has a height h5 and exerts a force F2 onto the underside of the upper semiconductor chip 1403.

As illustrated in FIGS. 14E-14H, the dummy wire 1416 may be aligned so that the non-connected end of the dummy wire 1416 is in a horizontal direction x1, x2, z1, or z2, relative to the connected end of the dummy wire 1416. For example, FIG. 14E illustrates a dummy wire 1416 that extends in the direction x1 from the connected end to the non-connected end. Alternatively, the non-connected end may be located in any direction relative to the connected end depending on desired design and function.

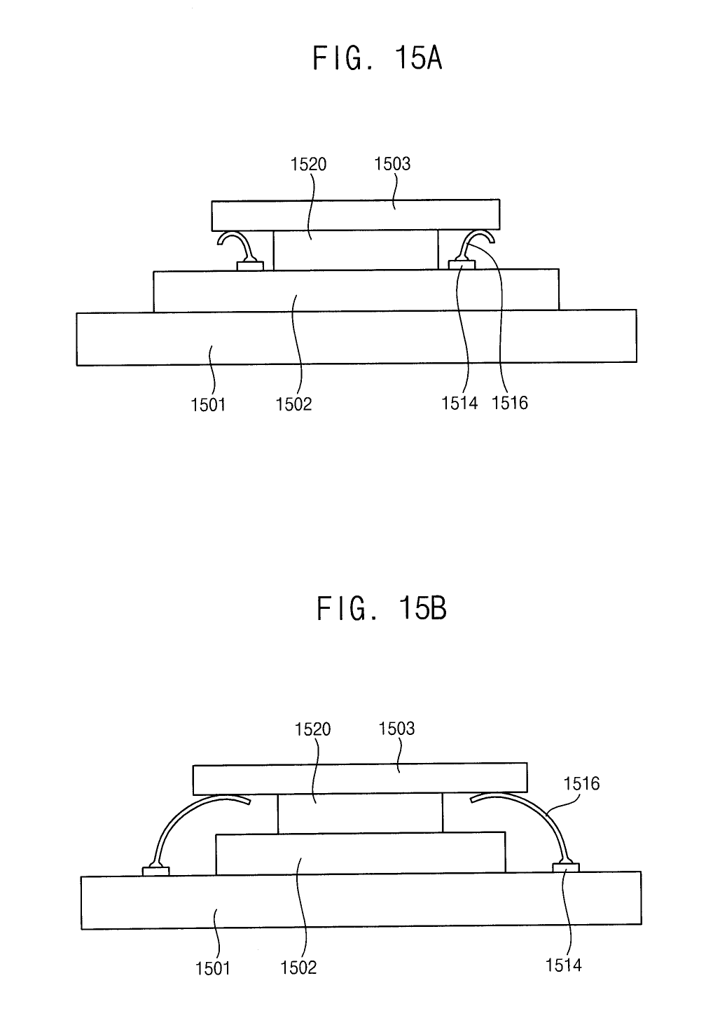

FIG. 15A illustrates a stacked semiconductor package 1500 similar to that of FIG. 8C. The stacked semiconductor package 1500 includes a substrate 1501, a lower semiconductor chip mounted 1502 mounted on the substrate 1501, an intermediate semiconductor chip 1520 mounted on the lower semiconductor chip 1502, and an upper semiconductor chip 1503 mounted on the intermediate semiconductor chip 1520. The semiconductor chips 1502, 1503 may be connected to the substrate and/or each other via wires and connection pads (not shown in FIG. 15A). The upper semiconductor chip 1503 may overhang the intermediate semiconductor chip 1520. A bonding pad 1514 may be formed on the lower semiconductor chip 1502 beneath the overhang of the upper semiconductor chip 1503. A dummy wire 1516 may be formed on the bonding pad 1514 to support the bottom surface of the upper semiconductor chip 1503. An end of the dummy wire 1516 may be unconnected to any bonding pad.

FIG. 15B is similar to FIG. 15A, except that instead of a bonding pad 1514 being formed on the lower semiconductor chip 1502, the bonding pad 1514 is formed on the substrate 1501. The dummy wire 1516 may extend from the bonding pad 1514 of the substrate 1501 to contact a bottom surface of the overhang portion of the upper semiconductor chip 1503.

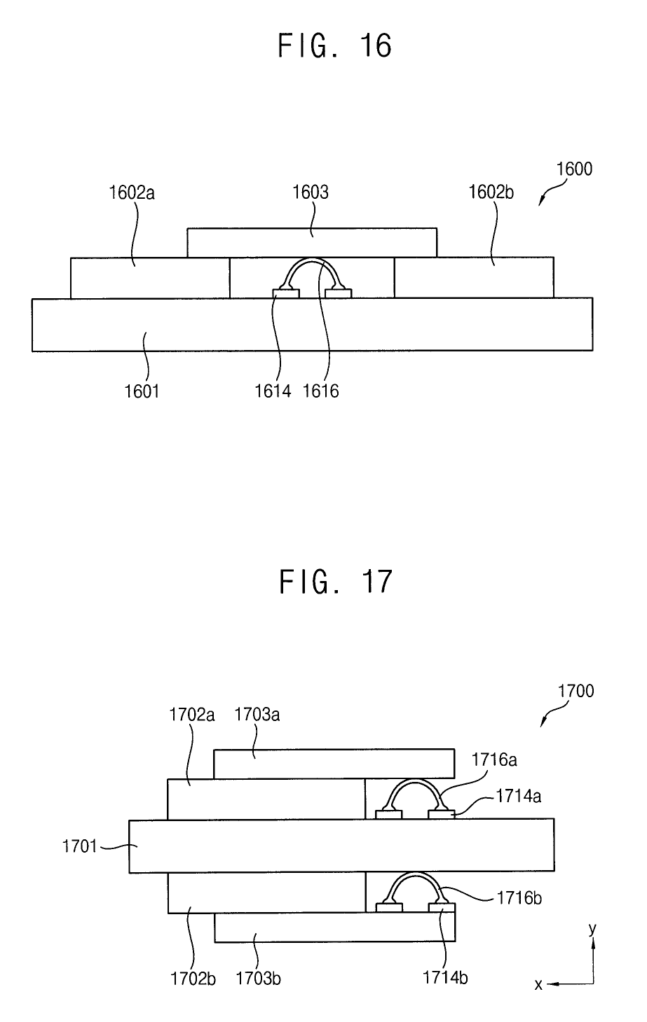

FIG. 16 illustrates a stacked semiconductor package 1600 according to another embodiment of the present general inventive concept. The stacked semiconductor package 1600 may include two lower semiconductor chips 1602a, 1602b positioned on a substrate 1601 with a space between the semiconductor chips 1602a, 1602b. An upper semiconductor chip 1603 may be stacked on the lower semiconductor chips 1602a, 1602b so that a center portion of the upper semiconductor chip 1603 is over the space between the lower semiconductor chips 1602a, 1602b. Connection pads and wires (not shown in FIG. 16) may connect the semiconductor chips to the substrate 1601 and/or to each other.

Connection pads 1614 may be formed in the space between the lower semiconductor chips 1602a, 1602b, and a dummy wire 1616 may be formed to extend between two connection pads 1614 and to have an apex that contacts the bottom surface of the upper semiconductor chip 1603.

Although above embodiments have included a dummy wire having an apex that contacts a semiconductor chip, the dummy wire may also be flipped so that its apex contacts a substrate, such as a circuit board.

FIG. 17 illustrates a stacked semiconductor package 1700 having semiconductor chips on both sides of a substrate 1701, such as a circuit board. In the description below, the components will be discussed with respect to the substrate 1701, so that “upper” refers to “farther from the substrate” and “lower” refers to “closer to the substrate.” Lower semiconductor chip 1702a may be mounted to a first side of the substrate 1701, and lower semiconductor chip 1702b may be mounted to the other side of the substrate 1701. Upper semiconductor chips 1703a and 1703 may be mounted to the respective lower semiconductor chips 1702a, 1702b and a portion of the upper semiconductor chips 1703a, 1703b may overhang the lower semiconductor chips 1702a, 1702b. As discussed in previous figures, connection pads 1714a may be formed on the substrate 1701 and a dummy wire 1716a may be formed between the connection pads 1714a and may have an apex that contacts a lower surface of the overhang portion of the upper semiconductor chip 1703a. In other words, the dummy wire 1716a may extend in the direction y from the connection end to the apex.

On the other hand, connection pads 1714b may also be formed on a lower surface of the upper semiconductor chip 1714b, and so that the connection ends of the dummy wire 1716b extend in the direction y from the bottom surface of the upper semiconductor chip 1703b to the surface of the substrate 1701. In other words, while dummy wires of previous example embodiments have extended from connection end on a connection pad closer to the substrate to an apex contacting a semiconductor chip overhang portion, the dummy wire may also be flipped so that the connection end is connected to the overhang portion and the apex contacts the substrate or a surface of a semiconductor chip closer to the substrate than the overhang portion.

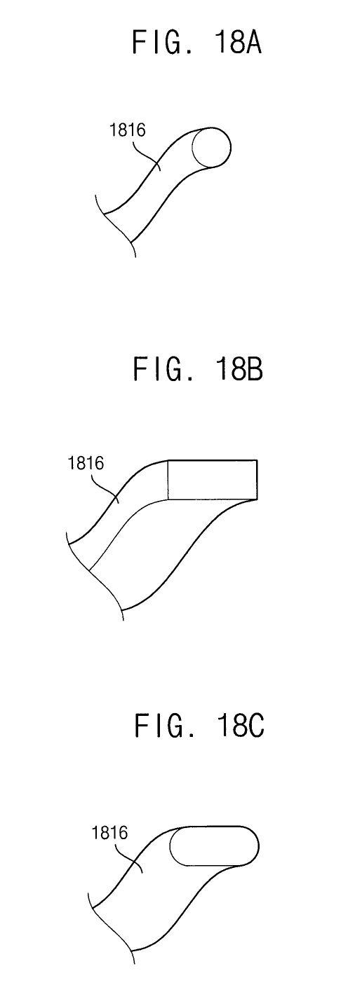

The dummy wires may be designed to have various thicknesses, shapes, and compositions. FIGS. 18A-18C illustrate dummy wires 1816 of various shapes. For example, the dummy wire 1816 may have a circular cross-section shape, a rectangular cross-section shape, or a not circular-rounded shape. Alternatively, the dummy wire may have any polygonal shape, or any combination of shapes along the same dummy wire.

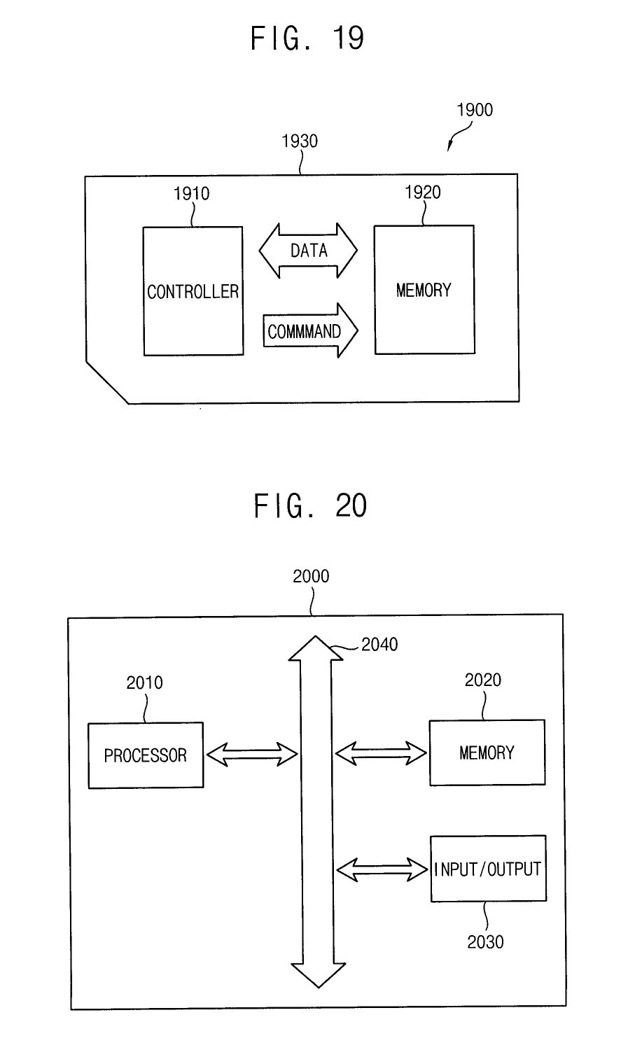

A stacked semiconductor package according to any one of the above embodiments may be included in a memory storage device, as illustrated in FIG. 19. The memory storage device 1900 may include a controller 1910 and memory 1920. The controller 1910 and memory 1920 may be enclosed within an outer casing 1930. The controller 1910 may receive external commands or predetermined commands and may access the memory 1920 to exchange data with the memory. At least one of the controller 1910 and the memory 1920 may include a stacked semiconductor package including one or more dummy wires, or using wires to support offset stacked semiconductor chips. A memory storage device 1900 may be a multimedia card, a secure digit device, a solid state drive, or any other memory storage device.

FIG. 20 illustrates a memory system or computing device 2000 including a stacked semiconductor package according to any one of the above embodiments. The computing device 2000 may include memory 2020, an input/output device or port 2030, and a processor 2010. The processor 2010 may receive commands via the I/O device 2030 or from memory 2020 and may then access either the memory 2020 or the I/O device in exchange data. The processor 2010, memory 2020, and I/O device 2030 may transmit data and/or commands via a data/command bus 2040. Any one of the processor 2010, the memory 2020, and the input/output device 2030 may include a stacked semiconductor package according to any one of the above embodiments.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor package, comprising:
a circuit board;
a first semiconductor chip mounted to the circuit board to be separated from the circuit board by a predetermined distance; and
a first support located between the circuit board and the first semiconductor chip to support the first semiconductor chip, the first support having first and second ends fixed with respect to the circuit board and a main portion between the first and second ends to contact the first semiconductor chip.

2. The semiconductor package according to claim 1, further comprising a second semiconductor chip mounted to the circuit board,
wherein the first semiconductor chip is mounted to an upper surface of the second semiconductor chip,
an overhang portion of the first semiconductor chip extends past an end of the second semiconductor chip in a first direction, and
the main portion of the first support contacts the overhang portion of the first semiconductor chip.

3. The semiconductor package according to claim 2, wherein the first support has a length that runs parallel to the first direction.

4. The semiconductor package according to claim 2, wherein the first support has a length that runs perpendicular to the first direction.

5. The semiconductor package according to claim 2, wherein the first support includes a first wire having a length running perpendicular to the first direction and a second wire having a length running parallel to the first direction.

6. The semiconductor package according to claim 5, wherein one of the first and second wire is mounted to have a center portion beneath a center portion of the other of the first and second wire to support the other of the first and second wire.

7. The semiconductor package according to claim 2, further comprising:
a third semiconductor chip mounted to an upper surface of the first semiconductor chip,
wherein an overhang portion of the third semiconductor chip extends past an end of the overhang portion of the first semiconductor chip in the first direction, and
a second support to support the third semiconductor chip by contacting a bottom surface of the second overhang portion of the third semiconductor chip.

8. The semiconductor package according to claim 7, wherein the first support has a first height and the second support has a second height greater than the first height.

9. The semiconductor package according to claim 1, wherein the first and second ends of the first support are mounted to an upper surface of the circuit board.

10. The semiconductor package according to claim 1, wherein the first support comprises a wire.

11. The semiconductor package according to claim 10, wherein the wire is a dummy wire that does not transmit electrical signals from one end to the other end.

12. The semiconductor package according to claim 11, wherein the semiconductor package comprises at least one transmission wire to electrically connect a bonding pad of the first semiconductor chip to a bonding pad of the circuit board, and
the dummy wire has a thickness greater than a thickness of the transmission wire.

13. The semiconductor package according to claim 12, wherein the semiconductor package comprises at least one transmission wire to electrically connect a bonding pad of the first semiconductor chip to a bonding pad of the circuit board, and
the dummy wire is composed of a material different than the transmission wire.

14. The semiconductor package according to claim 10, wherein the support further comprises a polymer material to support the wire, and
the wire is positioned over an upper surface of the polymer material.

15. The semiconductor package according to claim 1, further comprising:
a second semiconductor chip mounted to the circuit board; and
a third semiconductor chip mounted to an upper surface of the second semiconductor chip to expose a bonding pad portion of the second semiconductor chip located on an upper surface of the second semiconductor chip,
wherein the first semiconductor chip is mounted to the third semiconductor chip,
an overhang portion of the first semiconductor chip extends past an end of the third semiconductor chip to be located over the bonding pad portion of the upper surface of the second semiconductor chip, and
another support is mounted to the bonding pad portion of the second semiconductor chip.

16. The semiconductor package according to claim 15, wherein each end of the another support is mounted to the bonding pad portion of the second semiconductor chip.

17. The semiconductor package according to claim 15, wherein a first end of the another support is mounted to the bonding pad portion of the second semiconductor chip, and
a second end of the another support is mounted to the circuit board.

18. A semiconductor package, comprising:
a circuit board;
a first semiconductor chip mounted to be fixed with respect to the circuit board and spaced from the circuit board by a predetermined distance; and
a first support mounted to the circuit board to provide support to the first semiconductor chip by providing a linear pressure to a bottom surface of the first semiconductor chip.

19. A semiconductor package, comprising:
a circuit board;
a first semiconductor chip electrically connected to the circuit board and spaced from the circuit board by a predetermined distance; and
a first support mounted to the circuit board to provide support to the first semiconductor chip by providing a linear pressure to a bottom surface of the first semiconductor chip.

20. A semiconductor package comprising:
a circuit board;
a semiconductor chip positioned over and spaced-apart from the circuit board by a predetermined distance and electrically connected to the circuit board; and
a first support mounted on the circuit board to support the semiconductor chip, the first support including at least two pads fixed to the circuit board and spaced apart from each other and a material connecting the at least two pads and contacting the semiconductor chip.

21. A semiconductor package comprising:
a circuit board;
a semiconductor chip electrically connected to the circuit board and spaced-apart from the circuit board by a predetermined distance; and
a first support mounted on the circuit board to support the semiconductor chip to maintain the predetermined distance with respect to the circuit board.

22. A semiconductor package comprising:
a circuit board;
a semiconductor chip positioned over the circuit board; and
a first support having a bottom formed on the circuit board in a first, lengthwise direction and a top having a height sufficient to contact the semiconductor chip,
wherein the top and at least two ends of the bottom form a substantially triangular shape.

23. A semiconductor package comprising:
a circuit board;
a semiconductor chip positioned over the circuit board; and
a first support having two ends formed on the circuit in a first, lengthwise direction and a top connected to the two ends and forming an arch shape having a height sufficient to contact the semiconductor chip.

24. A semiconductor package comprising:
a circuit board;
a semiconductor chip; and
a first support having a bottom to contact with the circuit board in a first geometric area of the circuit board and a top to contact the semiconductor chip in a second geometric area of the semiconductor chip,
wherein the first geometric area has a non-circular shape and the second geometric area has a substantially rectangular shape.

25. A semiconductor package comprising:
a circuit board;
a semiconductor chip; and
a first support to support the semiconductor chip, to contact the circuit board in a geometric area of the circuit board, and to contact the semiconductor chip along a geometric line segment.

26. A semiconductor package comprising:
a circuit board;
a semiconductor chip in a fixed position with respect to the circuit board; and
a support to support the semiconductor chip by contacting the circuit board in a first geometric area of the circuit board and to contact the semiconductor chip in a second geometric area of the semiconductor chip,
wherein the first geometric area is different from the second geometric area.

27. A semiconductor package comprising:
a circuit board;
a first semiconductor chip positioned over a first area of the circuit board;
a second semiconductor chip positioned over a second area of the circuit board, the second area having an overlapping area and a non-overlapping area with the first area; and
a support located in the non-overlapping area and having a length in a first direction and a width in a second direction,
wherein the length is longer than the width.

28. A semiconductor package comprising:
a circuit board;
a support formed on the circuit board and having a length in a first direction; and
a semiconductor chip positioned a predetermined distance over the circuit board in a longitudinal direction having a predetermined angle with respect to the first direction, the semiconductor chip contacting the support and being electrically connected to the circuit board.

29. The semiconductor package of claim 18, wherein:
the support has a length and a width; and
at least one of the length and width is greater than the other one of the length and width.

30. The semiconductor package of claim 18, wherein:
the support comprises at least two ends separated from each other to contact the circuit board, and a middle portion connecting the two ends to contact the semiconductor chip.

31. The semiconductor package of claim 18, wherein:
the support has a height substantially same as the predetermined distance between the semiconductor chip and the circuit board.

32. The semiconductor package of claim 18, wherein:
the support is an elastic material.

33. The semiconductor package of claim 18, wherein:
the support comprises a polymer.

34. The semiconductor package of claim 18, further comprising a second semiconductor chip mounted to the circuit board,
wherein the support is mounted on the second semiconductor chip to support the first semiconductor chip.

35. The semiconductor package of claim 18, further comprising:
a second semiconductor chip positioned between the circuit board and the semiconductor chip and positioned in a direction different from the first semiconductor chip,
wherein the support is positioned in a direction parallel to one of the first semiconductor and the second semiconductor.

36. An electronic apparatus comprising:
a circuit board;
a first semiconductor chip mounted to be fixed with respect to the circuit board and spaced from the circuit board by a predetermined distance; and
a support mounted to the circuit board to provide support to the first semiconductor chip by providing a linear pressure to a bottom surface of the first semiconductor chip.

37. A memory storage device, comprising:
a memory unit including a stacked semiconductor package, the semiconductor package comprising:
a circuit board;
a first semiconductor chip mounted to the circuit board to be separated from the circuit board by a predetermined distance; and
a support located between the circuit board and the first semiconductor chip to support the first semiconductor chip, the support having first and second ends fixed with respect to the circuit board and a center portion between the first and second ends to contact the first semiconductor chip; and
a controller to read data from and write data to the stacked semiconductor package.
